(19) United States
(12) Patent Application Publication
(10) Pub. No.: US 2024/0429307 A1
(43) Pub. Date: Dec. 26, 2024

(54) SYSTEMS AND METHODS OF APPLYING STRESS IN TRANSISTORS

(71) Applicant: Samsung Electronics Co., Ltd., Suwon-si (KR)

(72) Inventors: Rebecca PARK, Mountain View, CA (US); Mehdi SAREMI, Danville, CA (US); Ming HE, San Jose, CA (US); Muhammed AHOSAN UL KARIM, San Jose, CA (US); Aravindh KUMAR, Mountain View, CA (US); Harsono SIMKA, Saratoga, CA (US)

(21) Appl. No.: 18/745,976

(22) Filed: Jun. 17, 2024

Related U.S. Application Data
(60) Provisional application No. 63/522,409, filed on Jun. 21, 2023.

(51) Int. Cl. H01L 29/66; H01L 29/417; H01L 29/78

(52) U.S. Cl. CPC H01L 29/66545; H01L 29/41791; H01L 29/66795; H01L 29/785

(57) ABSTRACT

Provided are systems, methods, and apparatuses for applying stress in transistors. In one or more examples, the systems, devices, and methods include depositing an epitaxial film on a surface between a first sidewall and a second sidewall of the transistor; depositing a dielectric over the epitaxial film and on the surface between the first sidewall and the second sidewall to increase stress in a silicon channel of the transistor; removing a polysilicon fin between the second sidewall and a third sidewall; and depositing a first metal between the second sidewall and the third sidewall based on removing the polysilicon fin.

### CROSS-REFERENCE TO RELATED APPLICATIONS

This application claims the benefit of U.S. Provisional Patent Application Ser. No. 63/522,409, filed Jun. 21, 2023, which is incorporated by reference herein for all purposes.

### TECHNICAL FIELD

The disclosure relates generally to semiconductor fabrication, and more particularly to applying stress in transistors.

### BACKGROUND

The present background section is intended to provide context only, and the disclosure of any concept in this section does not constitute an admission that said concept is prior art.

A transistor is a semiconductor device that can amplify or switch electronic signals and electrical power. Transistors are the basic building blocks of modern electronics and can act as switches, amplifiers, signal regulators, etc. Metal-oxide-semiconductor field-effect transistors (MOSFETs) are a type of field-effect transistor (FET) that are commonly used in electronics as amplifiers and electrical switches. MOSFETs can control the amount of electricity that can flow between the source and drain terminals based on the voltage applied to the gate terminal.

### SUMMARY

In various embodiments, the systems and methods described herein include systems, methods, and apparatuses for applying stress in transistors. In some aspects, the techniques described herein relate to a method of fabricating a transistor, the method including: depositing an epitaxial film on a surface between a first sidewall and a second sidewall of the transistor; depositing a dielectric over the epitaxial film and on the surface between the first sidewall and the second sidewall to increase stress in a silicon channel of the transistor; removing a polysilicon fin between the second sidewall and a third sidewall; and depositing a first metal between the second sidewall and the third sidewall based on removing the polysilicon fin.

In some aspects, the techniques described herein relate to a method, further including removing the dielectric between the first sidewall and the second sidewall, wherein depositing the first metal maintains the stress on the silicon channel after removal of the dielectric.

In some aspects, the techniques described herein relate to a method, further including depositing a second metal between the first sidewall and the second sidewall based on removing the dielectric.

In some aspects, the techniques described herein relate to a method, wherein: the epitaxial film includes a first epitaxy portion and a second epitaxy portion, and the dielectric is deposited over the epitaxial film before the first epitaxy portion is allowed to merge with the second epitaxy portion.

In some aspects, the techniques described herein relate to a method, further including removing, between the second sidewall and the third sidewall, a portion of a first silicon germanium layer formed under the silicon channel and a portion of a second silicon germanium layer formed over the silicon channel, wherein removing the first silicon germanium layer and the second silicon germanium layer decreases the stress in the silicon channel.

In some aspects, the techniques described herein relate to a method, further including etching a portion of a channel fin between the first sidewall and the second sidewall to form the surface between the first sidewall and the second sidewall.

In some aspects, the techniques described herein relate to a method, further including forming the first sidewall, the second sidewall, and the third sidewall over the channel fin, wherein: the channel fin is transverse to the first sidewall, the second sidewall, and the third sidewall, and the channel fin includes the silicon channel.

In some aspects, the techniques described herein relate to a method, wherein removing the polysilicon fin increases the stress of the silicon channel of the transistor.

In some aspects, the techniques described herein relate to a method, wherein the surface between the first sidewall and the second sidewall is associated with a source region of the transistor or a drain region of the transistor.

In some aspects, the techniques described herein relate to a method, wherein an area between the second sidewall and the third sidewall is associated with a gate region of the transistor.

In some aspects, the techniques described herein relate to a transistor including: an epitaxial film deposited on a surface between a first sidewall and a second sidewall of the transistor; a dielectric deposited over the epitaxial film and on the surface between the first sidewall and the second sidewall to increase stress in a silicon channel of the transistor; and a first metal deposited between the second sidewall and the third sidewall based on removing the polysilicon fin, wherein a polysilicon fin between the second sidewall and a third sidewall is removed to allow the first metal to be deposited.

In some aspects, the techniques described herein relate to a transistor, further including a second metal deposited between the first sidewall and the second sidewall based on removing the dielectric between the first sidewall and the second sidewall.

In some aspects, the techniques described herein relate to a transistor, wherein: the epitaxial film includes a first epitaxy portion and a second epitaxy portion, and the dielectric is deposited over the epitaxial film before the first epitaxy portion is allowed to merge with the second epitaxy portion.

In some aspects, the techniques described herein relate to a transistor, further including removing, between the second sidewall and the third sidewall, a portion of a first silicon germanium layer formed under the silicon channel and a portion of a second silicon germanium layer formed over the silicon channel, wherein removing the first silicon germanium layer and the second silicon germanium layer decreases the stress in the silicon channel.

In some aspects, the techniques described herein relate to a transistor, further including a portion of a channel fin between the first sidewall and the second sidewall that is etched to form the surface between the first sidewall and the second sidewall.

In some aspects, the techniques described herein relate to a transistor, further including the first sidewall, the second sidewall, and the third sidewall formed over the channel fin, wherein: the channel fin is transverse to the first sidewall, the second sidewall, and the third sidewall, and the channel fin includes the silicon channel.

In some aspects, the techniques described herein relate to a transistor, wherein: the surface between the first sidewall and the second sidewall is associated with a source region of the transistor or a drain region of the transistor, and an area between the second sidewall and the third sidewall is associated with a gate region of the transistor.

In some aspects, the techniques described herein relate to a fabrication system including: a deposition controller to: deposit an epitaxial film on a surface between a first sidewall and a second sidewall of the transistor; deposit a dielectric over the epitaxial film and on the surface between the first sidewall and the second sidewall to increase stress in a silicon channel of the transistor; a removal controller to remove a polysilicon fin between the second sidewall and a third sidewall; and the deposition controller to deposit a first metal between the second sidewall and the third sidewall based on removal of the polysilicon fin.

In some aspects, the techniques described herein relate to a fabrication system, the removal controller being further configured to remove the dielectric between the first sidewall and the second sidewall, wherein depositing the first metal maintains the stress on the silicon channel after removal of the dielectric.

In some aspects, the techniques described herein relate to a fabrication system, the deposition controller being further configured to deposit a second metal between the first sidewall and the second sidewall based on removal of the dielectric.

A computer-readable medium is disclosed. The computer-readable medium can store instructions that, when executed by a computer, cause the computer to perform substantially the same or similar operations as described herein are further disclosed. Similarly, non-transitory computer-readable media, devices, and systems for performing substantially the same or similar operations as described herein are further disclosed.

The systems and methods described herein include multiple advantages and benefits. For example, the systems and methods include applying stress in transistors based on depositing dummy stressor materials to a source and/or drain region of a transistor before depositing a metal gate material (e.g., replacement metal gate). In some cases, replacement metal gate (RMG) can include a process that involves replacing sacrificial polysilicon gates with metal gates. In some systems, RMG may be referred to as gate-last, which refers to the metal gate electrode being deposited after the high temperature activation anneal. Depositing a dummy stress material to source/drain regions of a transistor before depositing a metal gate material improves stress transfer efficiency and avoids the issues of reduced stress that can occur as a result of discontinuous epitaxial growth. Depositing a dummy stress material to source/drain regions of a transistor before depositing a metal gate material provides an optimal amount of stress to a silicon channel of a transistor.

### BRIEF DESCRIPTION OF THE DRAWINGS

The above-mentioned aspects and other aspects of the present systems and methods will be better understood when the present application is read in view of the following figures in which like numbers indicate similar or identical elements. Further, the drawings provided herein are for purpose of illustrating certain embodiments only; other embodiments, which may not be explicitly illustrated, are not excluded from the scope of this disclosure.

These and other features and advantages of the present disclosure will be appreciated and understood with reference to the specification, claims, and appended drawings wherein:

FIGS. 1-20 illustrate example systems in accordance with one or more implementations as described herein.

FIG. 21 depicts a flow diagram illustrating an example method associated with the disclosed systems, in accordance with example implementations described herein.

FIG. 22 depicts a flow diagram illustrating an example method associated with the disclosed systems, in accordance with example implementations described herein.

FIG. 23 illustrate an example system in accordance with one or more implementations as described herein.

While the present systems and methods are susceptible to various modifications and alternative forms, specific embodiments thereof are shown by way of example in the drawings and will herein be described. The drawings may not be to scale. It should be understood, however, that the drawings and detailed description thereto are not intended to limit the present systems and methods to the particular form disclosed, but to the contrary, the intention is to cover all modifications, equivalents, and alternatives falling within the spirit and scope of the present systems and methods as defined by the appended claims.

### DETAILED DESCRIPTION OF VARIOUS EMBODIMENTS

The details of one or more embodiments of the subject matter described herein are set forth in the accompanying drawings and the description below. Other features, aspects, and advantages of the subject matter will become apparent from the description, the drawings, and the claims.

Various embodiments of the present disclosure now will be described more fully hereinafter with reference to the accompanying drawings, in which some, but not all embodiments are shown. Indeed, the disclosure may be embodied in many forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used to be examples with no indication of quality level. Like numbers refer to like elements throughout. Arrows in each of the figures depict bi-directional data flow and/or bi-directional data flow capabilities. The terms “path,” “pathway” and “route” are used interchangeably herein.

As should be appreciated, various embodiments of the present disclosure may be implemented as methods, apparatus, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may take the form of an entirely hardware embodiment, an entirely computer program product embodiment, and/or an embodiment that comprises a combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (for example the executable instructions, instructions for execution, program code, and/or the like) on a computer-readable storage medium for execution. For example, retrieval, loading, and execution of code may be performed sequentially, such that one instruction is retrieved, loaded, and executed at a time. In some example embodiments, retrieval, loading, and/or execution may be performed in parallel, such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not be necessarily all referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. Similarly, various waveforms and timing diagrams are shown for illustrative purpose only. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and case of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on chip (SoC), an assembly, and so forth.

The following description is presented to enable one of ordinary skill in the art to make and use the subject matter disclosed herein and to incorporate it in the context of particular applications. While the following is directed to specific examples, other and further examples may be devised without departing from the basic scope thereof.

Various modifications, as well as a variety of uses in different applications will be readily apparent to those skilled in the art, and the general principles defined herein may be applied to a wide range of embodiments. Thus, the subject matter disclosed herein is not intended to be limited to the embodiments presented, but is to be accorded the widest scope consistent with the principles and novel features disclosed herein.

In the description provided, numerous specific details are set forth in order to provide a more thorough understanding of the subject matter disclosed herein. It will, however, be apparent to one skilled in the art that the subject matter disclosed herein may be practiced without necessarily being limited to these specific details. In other instances, well-known structures and devices are shown in block diagram form, rather than in detail, in order to avoid obscuring the subject matter disclosed herein.

All the features disclosed in this specification, (including, for example, any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Various features are described herein with reference to the figures. It should be noted that the figures are only intended to facilitate the description of the features. The various features described are not intended as an exhaustive description of the subject matter disclosed herein or as a limitation on the scope of the subject matter disclosed herein. Additionally, an illustrated example need not have all the aspects or advantages shown. An aspect or an advantage described in conjunction with a particular example is not necessarily limited to that example and can be practiced in any other examples even if not so illustrated, or if not so explicitly described.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the Claims herein is not intended to invoke the provisions of 35 U.S.C. 112, Paragraph 6.

Please note, if used, the labels left, right, front, back, top, bottom, forward, reverse, clockwise and counter clockwise have been used for convenience purposes only and are not intended to imply any particular fixed direction. Instead, the labels are used to reflect relative locations and/or directions between various portions of an object.

Moreover, the terms “system,” “component,” “module,” “interface,” “model,” or the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers.

Unless explicitly stated otherwise, each numerical value and range may be interpreted as being approximate as if the word “about” or “approximately” preceded the value of the value or range. Signals and corresponding nodes or ports might be referred to by the same name and are interchangeable for purposes here.

While embodiments may have been described with respect to circuit functions, the embodiments of the subject matter disclosed herein are not limited. Possible implementations, may be embodied in a single integrated circuit, a multi-chip module, a single card, system-on-a-chip, or a multi-card circuit pack. As would be apparent to one skilled in the art, the various embodiments might also be implemented as part of a larger system. Such embodiments may be employed in conjunction with, for example, a digital signal processor, microcontroller, field-programmable gate array, application-specific integrated circuit, or general-purpose computer.

As would be apparent to one skilled in the art, various functions of circuit elements may also be implemented as processing blocks in a software program. Such software may be employed in, for example, a digital signal processor, microcontroller, or general-purpose computer. Such software may be embodied in the form of program code embodied in tangible media, such as magnetic recording media, optical recording media, solid-state memory, floppy diskettes, CD-ROMs, hard drives, or any other non-transitory machine-readable storage medium, that when the program code is loaded into and executed by a machine, such as a computer, the machine becomes an apparatus for practicing the subject matter disclosed herein. When implemented on a general-purpose processor, the program code segments combine with the processor to provide a unique device that operates analogously to specific logic circuits. Described embodiments may also be manifest in the form of a bit stream or other sequence of signal values electrically or optically transmitted through a medium, stored magnetic-field variations in a magnetic recording medium, etc., generated using a method and/or an apparatus as described herein.

In some cases, a channel region of a p-channel metal-oxide semiconductor (PMOS) transistor may be configured with compressive stress (e.g., −1 GigaPascal (GPa), negative compression) to boost hole mobility, while a channel region of an n-channel metal-oxide semiconductor (NMOS) transistor may be configured with tensile stress (e.g., +1 GPa, positive compression) to boost electron mobility. It is noted that a negative stress (e.g., −1.5 GPa) may be referred to as compressive stress, while a positive stress (e.g., +1.5 GPa) may be referred to as a tensile stress. Applying stress (e.g., to a silicon channel region of a transistor) can provide a performance boost. The strain in a channel region can depend on the intrinsic stress of the layer, thickness of the layer, and device dimensions. It is noted that “increasing stress” can be interpreted as increasing tensile stress or interpreted as increasing compressive stress in the channel region of NMOS transistors or in the channel region of PMOS transistors. Similarly, “decreasing stress” is interpreted as decreasing tensile stress or interpreted as decreasing compressive stress in the channel region of NMOS transistors or in the channel region of PMOS transistors.

Higher stress results in improved drive current. Stress engineering via epitaxial growth of source and drain has been one approach to boosting the performance in planar transistors and FinFETs. However, in some cases, an epitaxial stressor may not be an efficient stressor in advanced transistor structures having a discontinuous surface for source/drain epitaxial growth. In some cases, the presence of an inner spacer and/or bottom dielectric isolation (BDI) can result in a discontinuous surface for epitaxial growth. Discontinuous surfaces for epitaxial growth may result in defects, such as stacking faults and dislocations, which in turn may fail to provide a desired level of stress. For example, epitaxial film as a stressor may not provide reliable stress for some transistors, such as Multi-Bridge-Channel FETs (MBCFETs), Forksheet transistors, and Complementary FETs (CFETs) or Three-Dimensional Stack FET (3DS-FET) devices.

The systems and methods described herein provide a process to transfer stress into a transistor channel by depositing a stressor material in the source and drain region of the transistor. Additionally, the systems and methods provide a process for depositing the stressor material before depositing a metal gate (e.g., before replacement metal gate (RMG)), which improves stress transfer efficiency. The stress in the channel may be significantly greater when the stressor is deposited before the RMG compared to being deposited after the RMG. Depositing the stressor material before the RMG allows the RMG to lock in the stress profile. Thus, with the RMG locking in the stress profile, the stressor material can then be removed without adversely affecting the stress profile.

With some approaches, an epitaxial growth (e.g., epitaxial film) has been used as a stressor in the source and/or drain regions of a transistor. In some cases, a silicon germanium (SiGe) epitaxial film may be used as a stressor (e.g., for PMOS transistors). In some cases, a silicon carbide (SiC) epitaxial film may be used as a stressor (e.g., for NMOS transistors). With some transistors, the epitaxial film may result in a discontinuous surface in the epitaxial film (e.g., discontinuous or disjointed epitaxial growth). A discontinuous surface in the epitaxial film may cause defects (i.e., stacking faults, dislocation, etc.). Hardware Transmission Electron Microscopy (TEM) images have shown defects in such epitaxial films, and modeling results show stress reduction (e.g., reduced stress in a channel of a transistor, silicon channel region) due to such defects, which results in lower drive current. Thus, a source/drain epitaxial film as a stressor appears to be an inefficient stressor for some transistor devices.

The systems and methods described herein may use materials other than epitaxial films for stressor materials. The systems and methods may include depositing a material having a high intrinsic stress to transfer the stress into a silicon channel region. The systems and methods may be applicable to transistor structures that do not allow a continuous surface for epitaxial growth of source/drain.

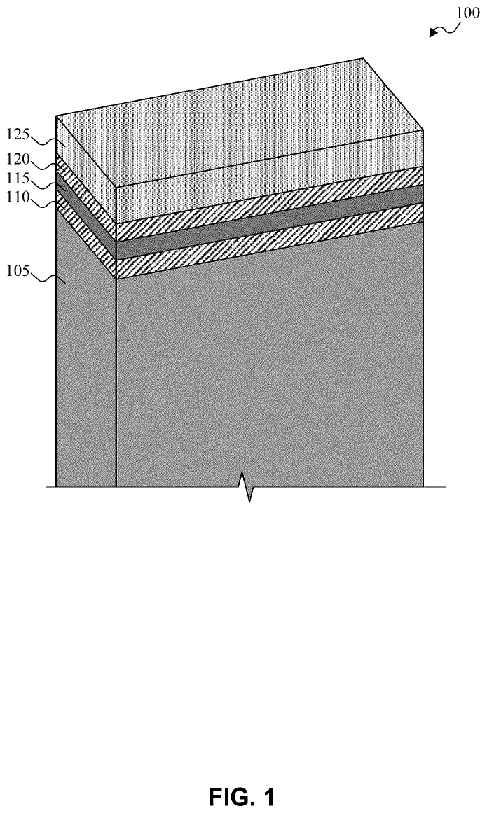

FIG. 1 illustrates an example stack 100 in accordance with one or more implementations as described herein. In some examples, stack 100 may depict layers of a semiconductor device (e.g., a semiconductor stack of a transistor). In the illustrated example, stack 100 may include a substrate 105, a semiconductor alloy 110, a semiconductor 115, a semiconductor alloy 120, and a nitride 125 (e.g., silicon nitride). In some examples, semiconductor alloy 110 may be deposited on substrate 105, semiconductor 115 may be deposited on semiconductor alloy 110, semiconductor alloy 120 may be deposited on semiconductor 115, and nitride 125 may be deposited on semiconductor alloy 120. In some examples, a transistor may be configured with one semiconductor channel (e.g., semiconductor 115). In some cases, a transistor may be configured with two or more semiconductor channels (e.g., based on a vertical stack, a taller stack).

In some examples, substrate 105 may include a silicon substrate. A contacted poly pitch (CPP), or transistor gate pitch, of stack 100 may be, for example, in the nanometer or micrometer scale. In some cases, semiconductor alloy 110 and/or semiconductor alloy 120 may include silicon germanium (SiGe). In some cases, semiconductor 115 may include silicon. Semiconductor 115 may form a silicon channel region of stack 100. A lattice mismatch may occur between semiconductor alloy 110, semiconductor 115, and semiconductor alloy 120, which can result in compressive stress in semiconductor alloy 110 and/or semiconductor alloy 120 (e.g., compressive stress in SiGe layers). For example, semiconductor alloy 110 and/or semiconductor alloy 110 may have a compressive stress at or relatively near-1.5 GPa. In stack 100, there may be relatively little to no stress in semiconductor 115 (e.g., in the silicon channel region). For example, semiconductor 115 may have a stress at or relatively near 0 GPa.

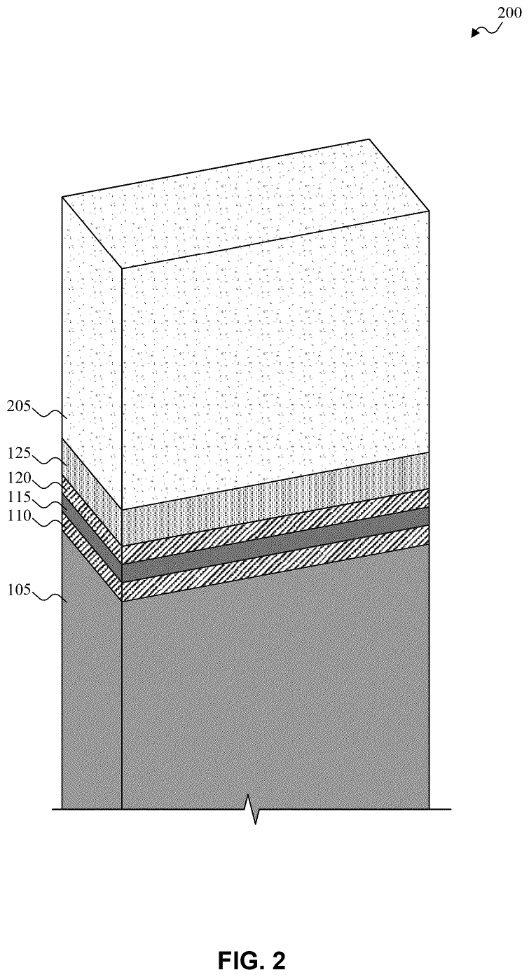

FIG. 2 illustrates an example stack 200 in accordance with one or more implementations as described herein. In some examples, stack 200 may depict layers of a semiconductor device (e.g., a semiconductor stack of a transistor). In the illustrated example, stack 200 may include substrate 105, semiconductor alloy 110, semiconductor 115, semiconductor alloy 120, nitride 125, and mask 205. In some cases, mask 205 may include a photoresist mask. A photoresist mask can include a light-sensitive material that is used to create a pattern or mask that blocks light from a surface in semiconductor fabrication. As shown, mask 205 may be deposited on nitride 125.

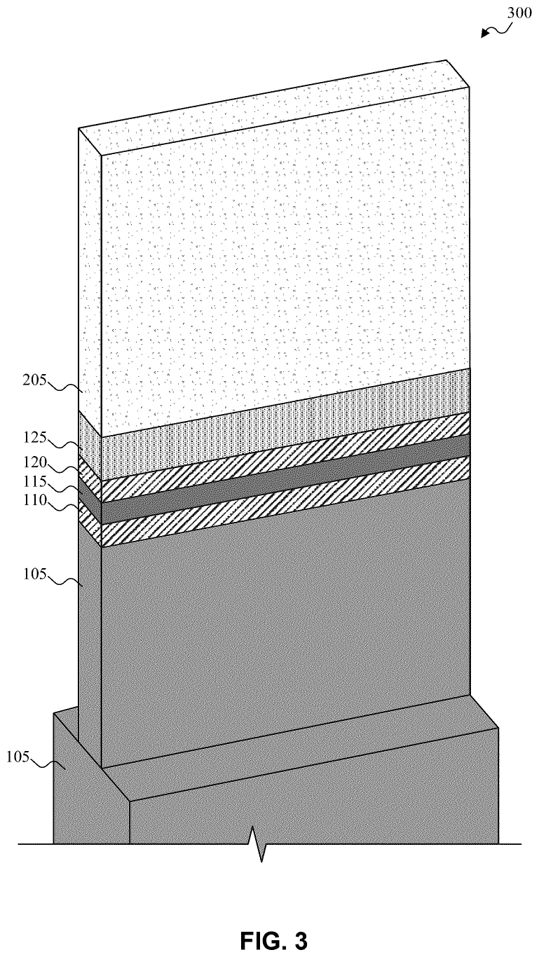

FIG. 3 illustrates an example stack 300 in accordance with one or more implementations as described herein. In some examples, stack 300 may depict layers of a semiconductor device (e.g., a semiconductor stack of a transistor). In the illustrated example, stack 300 may include substrate 105, semiconductor alloy 110, semiconductor 115, semiconductor alloy 120, nitride 125, and mask 205. In some cases, a portion of stack 300 (e.g., a portion of stack 200) may be removed. In the systems and methods described herein, portions of a stack (e.g., at least a portion of at least one layer) may be removed by etching (e.g., dry etching, wet etching, ashing. In some cases, chemicals may remove at least a portion of a layer. In some cases, gases may be used to remove at least a portion of a layer (e.g., ashing). As shown, a portion of substrate 105, semiconductor alloy 110, semiconductor 115, semiconductor alloy 120, nitride 125, and mask 205 may be etched to form a fin of stack 300 (e.g., form one or more fins, fins of stack 300). In some cases, the compressive stress in the semiconductor alloy 110 and/or semiconductor alloy 120 (e.g., in SiGe layers) may be relaxed based on the fin etch, resulting in a tensile stress in semiconductor 115 (e.g., in the silicon channel layer of an NMOS design). In some cases, a silicon channel of a transistor may be based on the fin of stack 300. Thus, the fin of stack 300 may be referred to as a channel fin. Although a line is shown between a base portion of substrate 105 and a fin portion of substrate 105, the base portion and the fin portion of substrate 105 of FIG. 3 (e.g., and other figures) may be contiguous as shown in FIGS. 1 and 2,

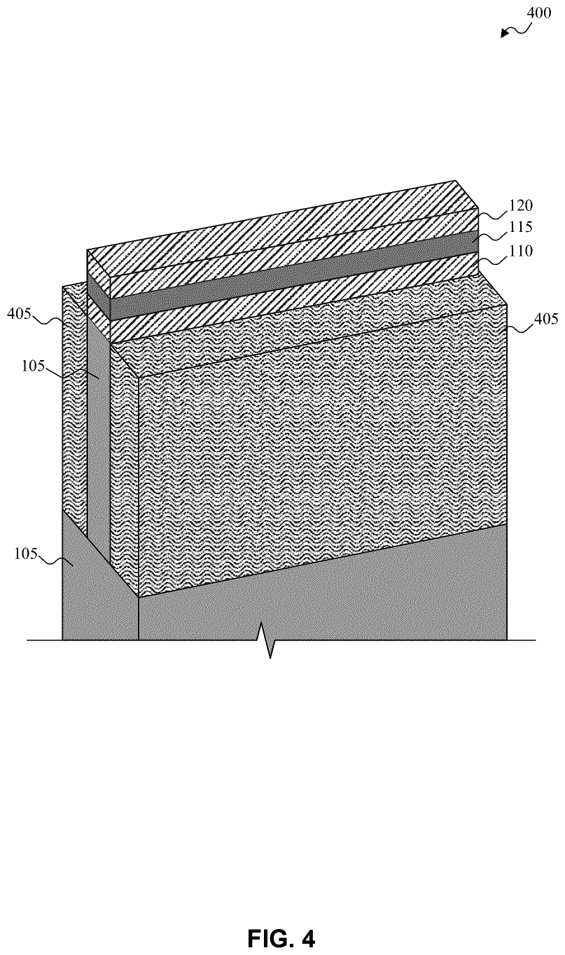

FIG. 4 illustrates an example stack 400 in accordance with one or more implementations as described herein. In some examples, stack 400 may depict layers of a semiconductor device (e.g., a semiconductor stack of a transistor). In the illustrated example, stack 400 may include substrate 105, semiconductor alloy 110, semiconductor 115, semiconductor alloy 120, and shallow trench isolation (STI) 405. Shallow trench isolation (STI), may be referred to as box isolation. STI may include an integrated circuit feature that prevents electric current leakage between adjacent semiconductor device components.

In some cases, a portion of stack 300 may be removed (e.g., via etching, dry etching, wet etching, etc.). As shown, a portion of stack 400 (e.g., a portion of stack 300) may be removed. For example, nitride 125 and mask 205 may be removed (e.g., via etching). As shown, STI 405 may be added to stack 400. In the illustrated example, a top surface of STI 405 may come up to or relatively near a bottom surface of semiconductor alloy 110. As shown, an inside surface of STI 405 may be adjacent to an outside surface of substrate 105 (e.g., a fin portion of substrate 105). In some cases, a relatively low or insignificant change in the stress profile of semiconductor 115 (e.g., silicon channel region) may occur as result of adding STI 405.

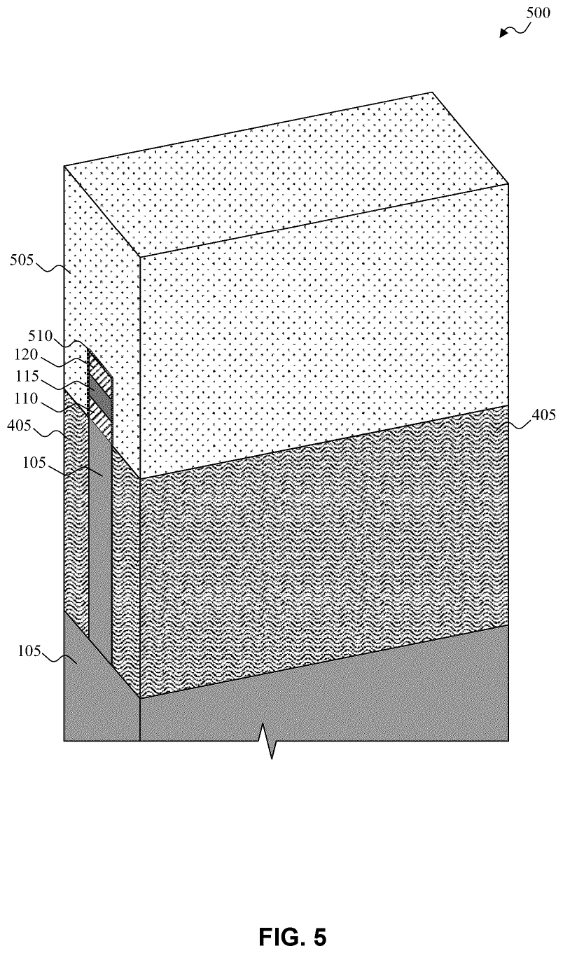

FIG. 5 illustrates an example stack 500 in accordance with one or more implementations as described herein. In some examples, stack 500 may depict layers of a semiconductor device (e.g., a semiconductor stack of a transistor). In the illustrated example, stack 500 may include substrate 105, semiconductor alloy 110, semiconductor 115, semiconductor alloy 120, STI 405, dummy gate 505, and oxide layer 510. In some cases, dummy gate 505 may include a semiconductor (e.g., polysilicon). Polysilicon (e.g., polycrystalline silicon) may include a metallurgical grade or high-purity form of silicon based on a chemical purification process. In some cases, a relatively low or insignificant change in the stress profile of semiconductor 115 (e.g., silicon channel region) may occur as result of adding dummy gate 505. In some cases, oxide layer 510 may include a dielectric (e.g., silicon oxide, silicon nitride, etc.). As shown, oxide layer 510 may be deposited over semiconductor alloy 110, semiconductor 115, semiconductor alloy 120 (e.g., before depositing dummy gate 505). As shown, dummy gate 505 (e.g., polysilicon) may be deposited over a surface of semiconductor alloy 120 and/or over a surface of STI 405 (e.g., over a first surface and a second surface of STI 405). As shown, dummy gate 505 may encapsulate semiconductor alloy 110, semiconductor 115, and semiconductor alloy 120.

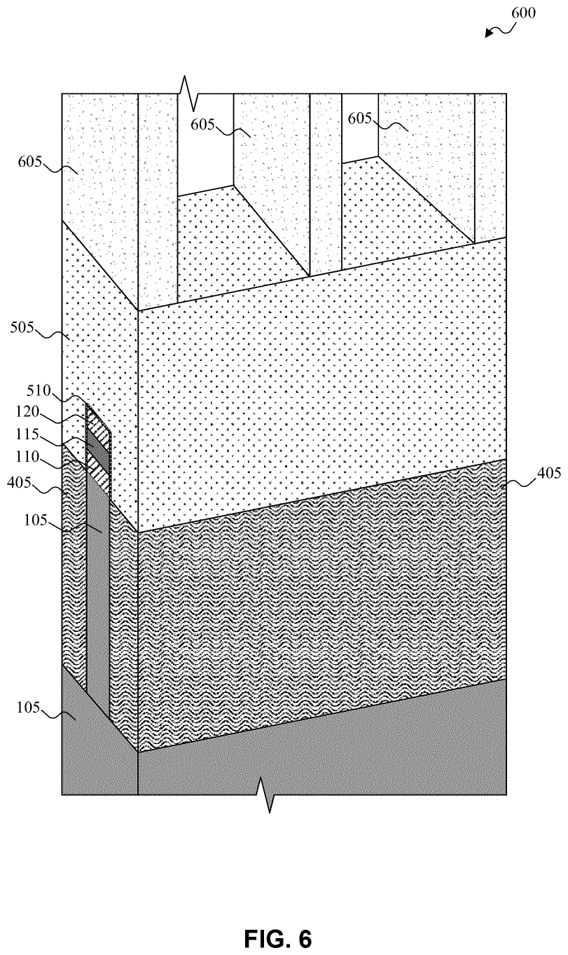

FIG. 6 illustrates an example stack 600 in accordance with one or more implementations as described herein. In some examples, stack 600 may depict layers of a semiconductor device (e.g., a semiconductor stack of a transistor). In the illustrated example, stack 600 may include substrate 105, semiconductor alloy 110, semiconductor 115, semiconductor alloy 120, STI 405, dummy gate 505, oxide layer 510, and mask 605. In some cases, mask 605 may include a photoresist mask. In some examples, mask 605 may be deposited on dummy gate 505 (e.g., a continuous layer of mask 605). In some cases, mask 605 may be etched to form one or more fins of mask 605, as shown. As shown, stack 600 may include fins of mask 605. In some cases, a relatively low or insignificant change in the stress profile of semiconductor 115 (e.g., silicon channel region) may occur as result of adding and/or etching mask 605.

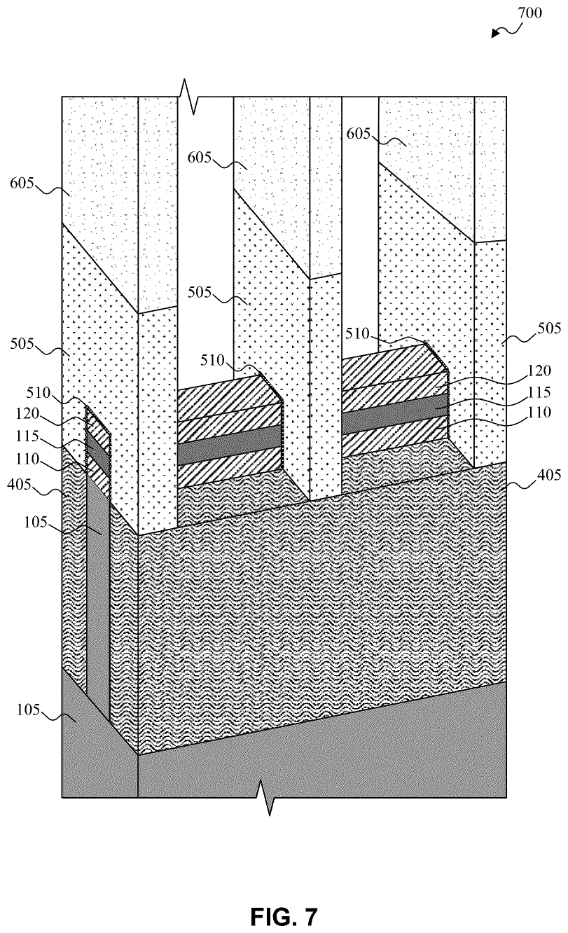

FIG. 7 illustrates an example stack 700 in accordance with one or more implementations as described herein. In some examples, stack 700 may depict layers of a semiconductor device (e.g., a semiconductor stack of a transistor). In the illustrated example, stack 700 may include substrate 105, semiconductor alloy 110, semiconductor 115, semiconductor alloy 120, STI 405, dummy gate 505, oxide layer 510, and mask 605. As shown, one or more etching processes may be applied to stack 700 (e.g., to stack 600) to form fins in mask 605 and fins in dummy gate 505. As shown, the etching process may expose portions of semiconductor alloy 110, semiconductor 115, and semiconductor alloy 120 between the fins of dummy gate 505 and mask 605. As shown, the fins of dummy gate 505 and mask 605 (e.g., fins of stack 700) may be formed to be transverse (e.g., orthogonal, at or relatively near 90 degrees) to the fin of stack 300 that is formed by etching a portion of substrate 105, semiconductor alloy 110, semiconductor 115, and semiconductor alloy 120.

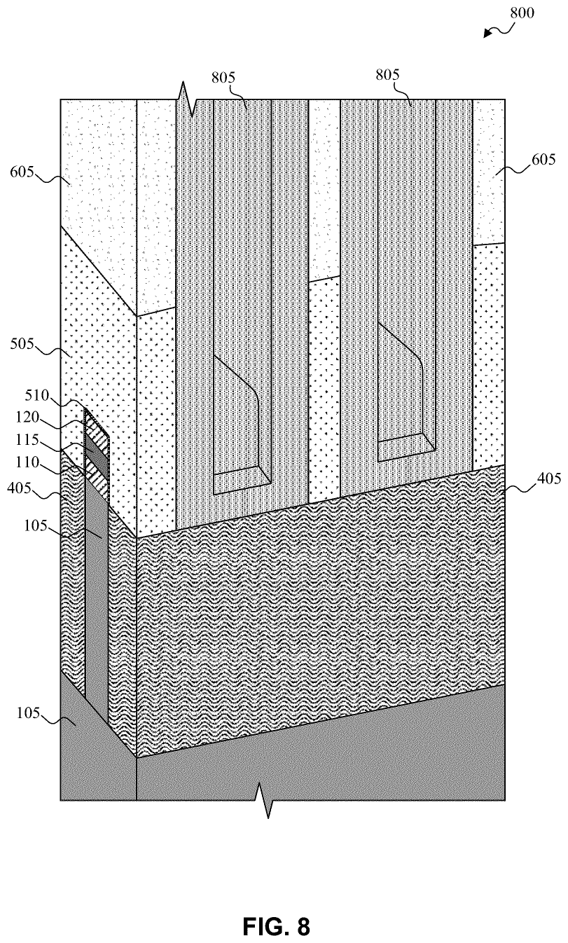

FIG. 8 illustrates an example stack 800 in accordance with one or more implementations as described herein. In some examples, stack 800 may depict layers of a semiconductor device (e.g., a semiconductor stack of a transistor). In the illustrated example, stack 800 may include substrate 105, semiconductor alloy 110, semiconductor 115, semiconductor alloy 120, STI 405, dummy gate 505, oxide layer 510, mask 605 (e.g., fins of dummy gate 505 and mask 605), and gate spacer 805. In some cases, gate spacers may be referred to as sidewalls. Gate spacers may insulate drain and source metal contacts from the gate of a transistor.

In some cases, gate spacer 805 may be deposited on stack 800 (e.g., on stack 700). In the illustrated example, gate spacer 805 may be deposited between the fins of dummy gate 505 and mask 605 (e.g., between the fins of stack 700). As shown, gate spacer 805 may be deposited over the portions of semiconductor alloy 110, semiconductor 115, and semiconductor alloy 120 that is exposed between the fins of dummy gate 505 based on the etching process of stack 700. As shown, gate spacer 805 may form sidewalls adjacent to the fins of dummy gate 505 and mask 605. In some cases, a relatively low or insignificant change in the stress profile of semiconductor 115 (e.g., silicon channel region) may occur as result of adding gate spacer 805.

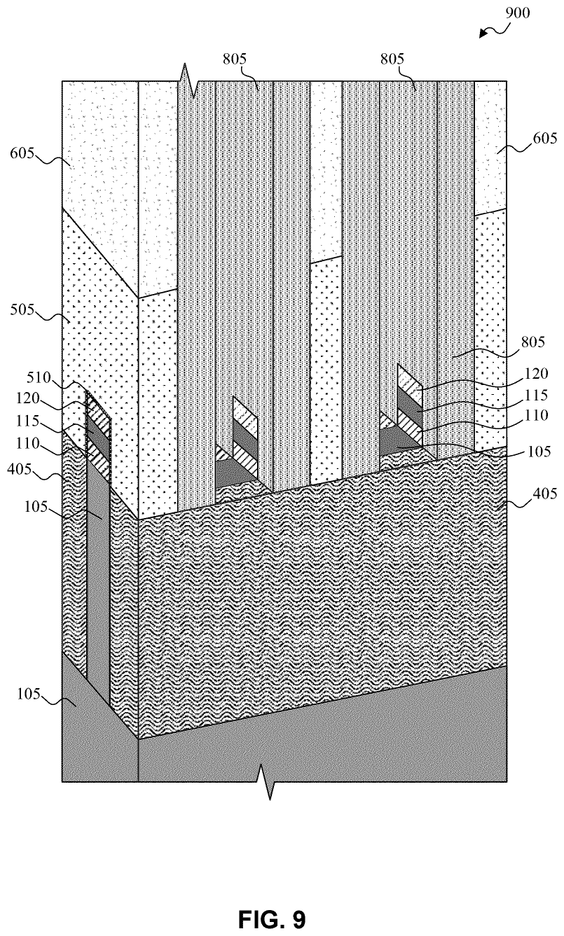

FIG. 9 illustrates an example stack 900 in accordance with one or more implementations as described herein. In some examples, stack 900 may depict layers of a semiconductor device (e.g., a semiconductor stack of a transistor). In the illustrated example, stack 900 may include substrate 105, segments of semiconductor alloy 110, segments of semiconductor 115, segments of semiconductor alloy 120, STI 405, and fins that include dummy gate 505, oxide layer 510, mask 605 (e.g., fins of dummy gate 505 and mask 605), and sidewalls of gate spacer 805.

In some examples, portions of gate spacer 805, semiconductor alloy 110, semiconductor 115, and/or semiconductor alloy 120 may be etched away. In the illustrated example, portions of gate spacer 805 between the fins of stack 900 and over semiconductor alloy 110, semiconductor 115, and semiconductor alloy 120 may be etched away. In the illustrated example, the fins of stack 900 may include the depicted fins of dummy gate 505 and mask 605 together with the sidewalls of gate spacer 805. As shown, portions of semiconductor alloy 110, semiconductor 115, and semiconductor alloy 120 between the fins of stack 900 may be etched away. Accordingly, portions of semiconductor alloy 110, semiconductor 115, and semiconductor alloy 120 may remain within or under the fins of stack 900 (e.g., embedded in the fins of stack 900).

In some cases, etching the portions of gate spacer 805 and the portions of semiconductor alloy 110, semiconductor 115, and semiconductor alloy 120 between the fins of stack 900 may reduce the compressive stress in the semiconductor alloy 110 and/or semiconductor alloy 120 (e.g., in SiGe layers). In some cases, reducing the compressive stress in the semiconductor alloy 110 and/or semiconductor alloy 120 results in increased tensile stress in semiconductor 115 (e.g., in the silicon channel of an NMOS design).

As shown, a gap or open area may be formed between the sidewalls of gate spacer 805 based on etching the portions of gate spacer 805 and the portions of semiconductor alloy 110, semiconductor 115, and semiconductor alloy 120 between the fins of stack 900. In some cases, the gap between the sidewalls of gate spacer 805 may be associated with a source region and/or a drain region of a transistor. The gap between the sidewalls of gate spacer 805 (e.g., source drain regions) may have no stress (e.g., based on the material removed in the source/drain regions). In some cases, an area filled with dummy gate 505 may be associated with a gate region of a transistor.

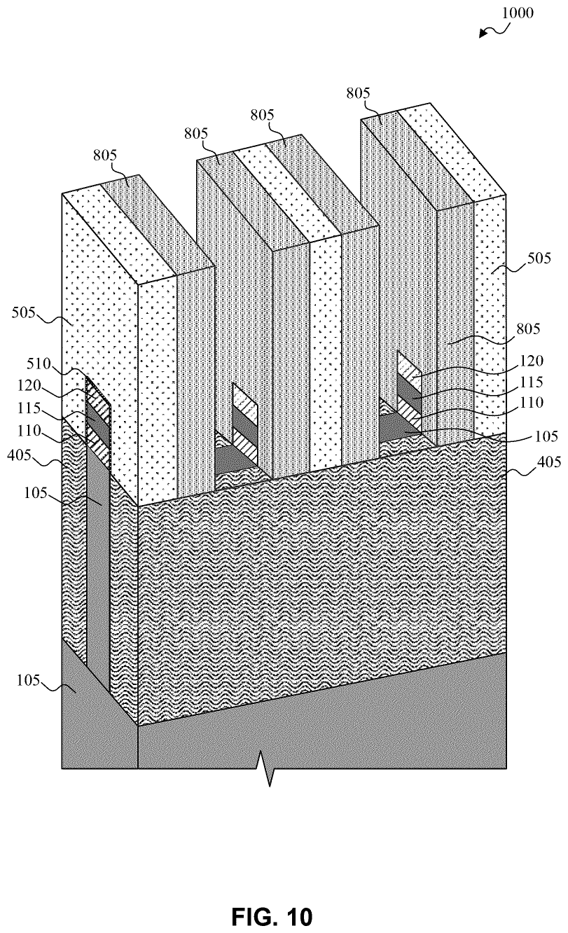

FIG. 10 illustrates an example stack 1000 in accordance with one or more implementations as described herein. In some examples, stack 1000 may depict layers of a semiconductor device (e.g., a semiconductor stack of a transistor). In the illustrated example, stack 1000 may include substrate 105, segments of semiconductor alloy 110, segments of semiconductor 115, segments of semiconductor alloy 120, STI 405, dummy gate 505, oxide layer 510, and sidewalls of gate spacer 805 (e.g., fins of dummy gate 505 and gate spacer 805).

In the illustrated example, mask 605 and a portion of the sidewalls of gate spacer 805 may be removed from stack 1000 (e.g., etched from stack 900), resulting in the depicted fins. As shown, FIG. 10 depicts three fins that include a portion of a first fin, a second fin, and a portion of a third fin. In some cases, FIG. 10 may depict three fins of a repeating pattern of 3 or more fins. A portion of the first fin is removed from view (e.g., a portion of the first fin sheared for illustration) to show the structure of the segments of semiconductor alloy 110, segments of semiconductor 115, and segments of semiconductor alloy 120 embedded within a given fin. As shown, the depicted first fin includes dummy gate 505 between sidewalls of gate spacer 805, where a first sidewall of gate spacer 805 is depicted, while the other sidewall of gate spacer 805 and a portion of dummy gate 505 are not shown for the first fin. The second fin depicts dummy gate 505 between a second sidewall of gate spacer 805 and a third sidewall of gate spacer 805. Thus, the second fin depicts a whole fin. The third fin depicts a fourth sidewall of gate spacer 805 and a portion of dummy gate 505, while the other sidewall of gate spacer 805 and a portion of dummy gate 505 are not shown for the third fin to show the contacted poly pitch (CPP), or transistor gate pitch, of stack 1000.

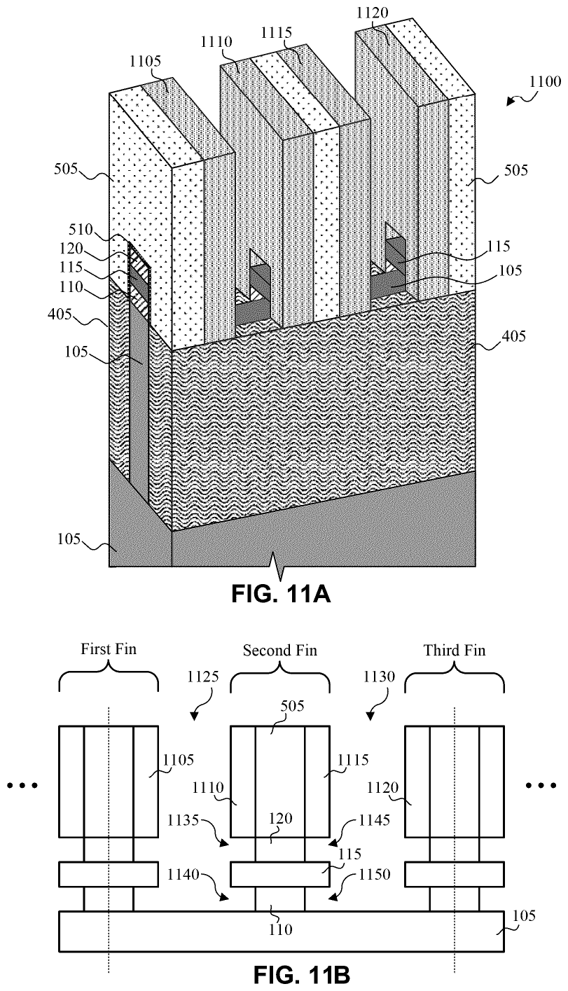

FIG. 11A illustrates an example stack 1100 in accordance with one or more implementations as described herein. In some examples, stack 1100 may depict layers of a semiconductor device (e.g., a semiconductor stack of a transistor). In the illustrated example, stack 1100 may include substrate 105, segments of semiconductor alloy 110, segments of semiconductor 115, segments of semiconductor alloy 120, STI 405, dummy gate 505, oxide layer 510, sidewalls of gate spacer 805 (e.g., fins of dummy gate 505 and gate spacer 805). Stack 1100 also depicts multiple sidewalls of gate spacer 805. As shown, the depicted sidewalls include first sidewall 1105, second sidewall 1110, third sidewall 1115, and fourth sidewall 1120 (e.g., sidewalls of gate spacer 805). As shown, a first portion of dummy gate 505 (e.g., sheared portion) is depicted adjacent to first sidewall 1105, first gap 1125 is depicted between first sidewall 1105 and second sidewall 1110, dummy gate 505 (e.g., a whole portion of dummy gate 505) is depicted between second sidewall 1110 and third sidewall 1115, second gap 1130 is depicted between third sidewall 1115 and fourth sidewall 1120, and a second portion of dummy gate 505 (e.g., sheared portion) is depicted adjacent to fourth sidewall 1120.

In the illustrated example, at least a portion of a segment of semiconductor alloy 110 and/or a segment of semiconductor alloy 120 may be removed from an outside edge of a given fin. For example, a portion of a segment of semiconductor alloy 110 and/or a segment of semiconductor alloy 120 that is under or within first sidewall 1105, second sidewall 1110, third sidewall 1115, and/or fourth sidewall 1120 may be removed.

In the illustrated example, one or more cavity formations may be formed in stack 1100. In some examples, portions of the segments of semiconductor alloy 110 and segments of semiconductor alloy 120 may be removed at the outside edges of a given fin. For example, portions of semiconductor alloy 110 and semiconductor alloy 120 under a given sidewall of gate spacer 805 may be removed, resulting in cavity formations in stack 1100, In some cases, the cavity formations may result in a reduction in compressive stress in the segments of semiconductor alloy 110 and segments of semiconductor alloy 120. In some cases, reducing compressive stress at the cavity formations may result in an increase in tensile stress in the segments of semiconductor 115 (e.g., in the segments of the silicon channel based on an NMOS design) within a given fin.

FIG. 11B illustrates a side view of stack 1100 in accordance with one or more implementations as described herein. In some examples, FIG. 11B may depict a side view of stack 1100 based on the three-dimensional view of stack 1100 of FIG. 11A. As shown, the side view of stack 1100 in FIG. 11B depicts a first fin, a second fin, and a third fin. The dotted lines depict where the portion of the first fin and the portion of the third fin are removed from view in FIG. 11A. As shown, first fin includes first sidewall 1105 (e.g., and another sidewall not shown in FIG. 11A); second fin includes second sidewall 1110, dummy gate 505, oxide layer 510, and third sidewall 1115; and the depicted third fin includes fourth sidewall 1120 (e.g., and another sidewall not shown in FIG. 11A).

In the illustrated example, at least a portion of a segment of semiconductor alloy 110 and/or a segment of semiconductor alloy 120 may be removed from an outside edge of a given fin. For example, a portion of a segment of semiconductor alloy 110 and/or a segment of semiconductor alloy 120 that is under or within second sidewall 1110 may be removed, resulting in cavity 1135 and cavity 1140. As shown, a portion of a segment of semiconductor alloy 110 and/or a segment of semiconductor alloy 120 that is under or within third sidewall 1115 may be removed, resulting in cavity 1145 and cavity 1150. As shown, a segment of semiconductor 115 remains within second fin and runs from one edge to the other edge of the second fin. Cavity 1135, cavity 1140, cavity 1145, and cavity 1150 may result in a reduction in compressive stress in the respective segments of semiconductor alloy 110 and segments of semiconductor alloy 120. In some cases, reducing compressive stress at the cavity formations may result in an increase in tensile stress in the segments of semiconductor 115 (e.g., in the segments of semiconductor 115 of the second fin based on an NMOS design).

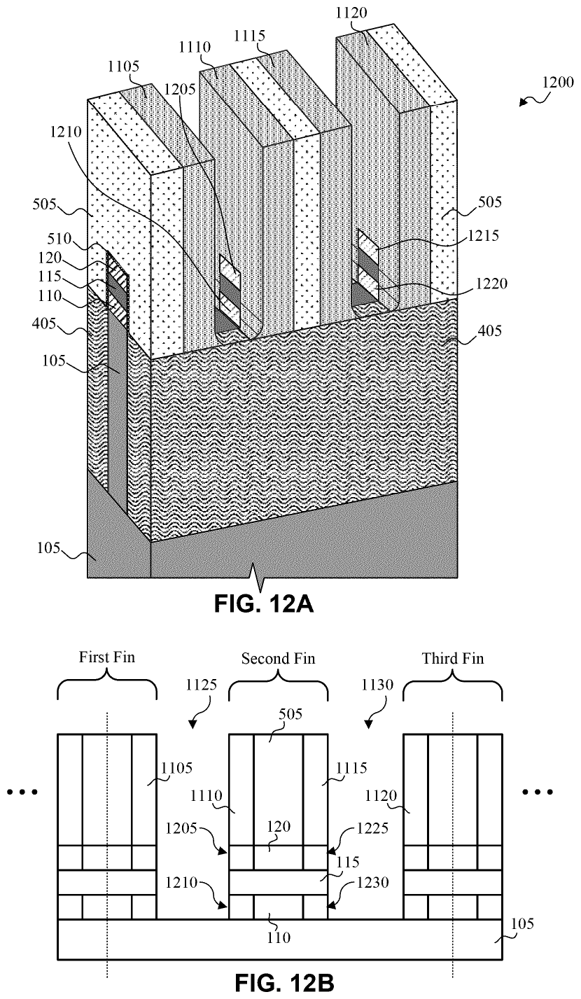

FIG. 12A illustrates an example stack 1200 in accordance with one or more implementations as described herein. In some examples, stack 1200 may depict layers of a semiconductor device (e.g., a semiconductor stack of a transistor). In the illustrated example, stack 1200 may include substrate 105, segments of semiconductor alloy 110, segments of semiconductor 115, segments of semiconductor alloy 120, STI 405, dummy gate 505, oxide layer 510, sidewalls of gate spacer 805 (e.g., fins of dummy gate 505 and gate spacer 805).

In the illustrated example, material may be deposited on stack 1200 that fills in the cavity formations (e.g., fills in the cavity formations of stack 1100). The material may be referred to as an inner spacer (e.g., inner spacer 1205, inner spacer 1210, inner spacer 1215, inner spacer 1220). In some cases, the inner spacer may include a nitride material.

FIG. 12B illustrates a side view of stack 1200 in accordance with one or more implementations as described herein. In some examples, FIG. 12B may depict a side view of stack 1200 based on the three-dimensional view of stack 1200 of FIG. 12A. As shown, the side view of stack 1200 in FIG. 12B depicts a first fin, a second fin, and a third fin. The dotted lines depict where the portion of the first fin and the portion of the third fin are removed from view in FIG. 12A. As shown, first fin includes first sidewall 1105 (e.g., and another sidewall not shown in FIG. 12A); second fin includes second sidewall 1110, dummy gate 505, oxide layer 510, and third sidewall 1115; and the depicted third fin includes fourth sidewall 1120 (e.g., and another sidewall not shown in FIG. 12A).

In the illustrated example, a first cavity formation of the second fin may be filled in with inner spacer 1205, a second cavity formation of the second fin may be filled in with inner spacer 1210, a third cavity formation of the second fin may be filled in with inner spacer 1225, and a fourth cavity formation of the second fin may be filled in with inner spacer 1230. As shown, one or more cavity formations of the first fin and/or the third find may be filled in with respective inner spacers.

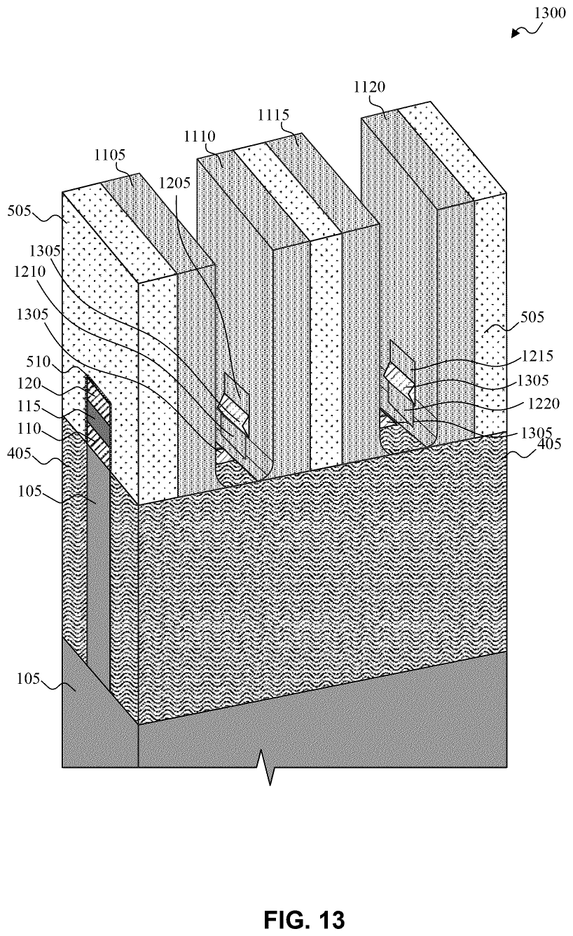

FIG. 13 illustrates an example stack 1300 in accordance with one or more implementations as described herein. In some examples, stack 1300 may depict layers of a semiconductor device (e.g., a semiconductor stack of a transistor). In the illustrated example, stack 1300 may include substrate 105, segments of semiconductor alloy 110, segments of semiconductor 115, segments of semiconductor alloy 120, STI 405, dummy gate 505, oxide layer 510, sidewalls of gate spacer 805 (e.g., fins of dummy gate 505 and gate spacer 805), inner spacer 1205, inner spacer 1210, inner spacer 1215, inner spacer 1220, and epitaxial film 1305.

In the illustrated example, epitaxial film 1305 may be grown between the fins of dummy gate 505 and gate spacer 805 (e.g., in the source/drain regions of stack 1300). As shown, one or more portions of epitaxial film 1305 may be deposited between first sidewall 1105 and second sidewall 1110, and/or deposited between third sidewall 1115 and fourth sidewall 1120. In some cases, epitaxial film 1305 may include SiGe for PMOS, Si or SiC for NMOS. In some cases, epitaxial film 1305 may not be allowed to merge. For example, the systems and methods may include a process where epitaxial film 1305 is not allowed to merge. As a result, a relatively insignificant change in the stress profile of the channel region may occur as a result of depositing unmerged epitaxial film 1305.

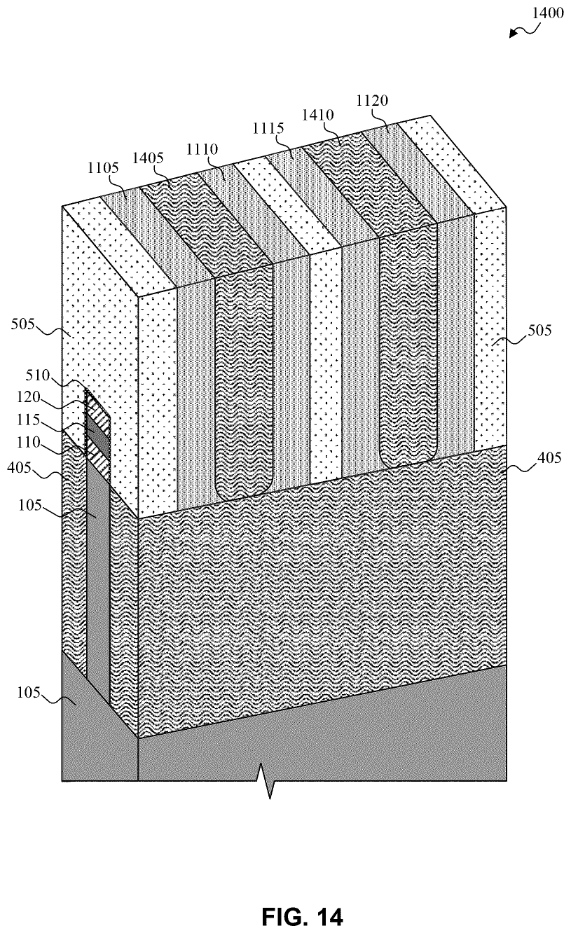

FIG. 14 illustrates an example stack 1400 in accordance with one or more implementations as described herein. In some examples, stack 1400 may depict layers of a semiconductor device (e.g., a semiconductor stack of a transistor). In the illustrated example, stack 1400 may include substrate 105, segments of semiconductor alloy 110, segments of semiconductor 115, segments of semiconductor alloy 120, STI 405, dummy gate 505, oxide layer 510, sidewalls of gate spacer 805 (e.g., fins of dummy gate 505 and gate spacer 805), stressor material 1405, and stressor material 1410. In some cases, portions of inner spacer 1205, inner spacer 1210, inner spacer 1215, inner spacer 1220, inner spacer 1225, inner spacer 1230, and/or epitaxial film 1305 may be embedded in or under sidewalls of gate spacer 805, stressor material 1405, and/or stressor material 1410.

In the illustrated example, a stressor material (e.g., stressor material 1405 and stressor material 1410) may be deposited between the fins of dummy gate 505 and gate spacer 805 (e.g., in the source/drain regions of stack 1400). As shown, stressor material 1405 may be deposited between first sidewall 1105 and second sidewall 1110, and/or stressor material 1410 may be deposited between third sidewall 1115 and fourth sidewall 1120.

In some examples, after depositing epitaxial film 1305, either compressive (for PMOS) or tensile (for NMOS) stressor material 1405 and stressor material 1410 may be added to the source region and the drain region of stack 1400. In some cases, the source region may be between first sidewall 1105 and second sidewall 1110, and the drain region may be between third sidewall 1115 and fourth sidewall 1120. In some cases, the drain region may be between first sidewall 1105 and second sidewall 1110, and the source region may be between third sidewall 1115 and fourth sidewall 1120. Depositing compressive (or tensile) stressor material 1405 and stressor material 1410 may apply compressive (or tensile) stress at the source and drain regions. For example, depositing stressor material with tensile stress at the source and drain regions may increase the tensile stress at the segments of semiconductor 115 (e.g., at the silicon channel region of stack 1400 based on an NMOS design). In some cases, stressor material 1405 and/or stressor material 1410 may include a dielectric, a metal, or a material that has intrinsic stress. In some cases, stressor material 1405 and stressor material 1410 may include at least one of aluminum oxide, moly-oxide, hafnium oxide, etc. Accordingly, the systems and methods provide mechanisms to add stress in a silicon channel of a transistor and efficiently transfer stress from stressor materials (e.g., stressor material 1405 and stressor material 1410) to the silicon channel. The systems and methods of inducing stress provide an increase in the drive current of a given transistor. In some cases, stressor material 1405 and/or stressor material 1410 may be deposited either before epitaxial film 1305 is merged (e.g. before epitaxial film crystals grow until touching) for maximal stress transfer from the stressor material 1405 and/or stressor material 1410 to the semiconductor 115, or after epitaxial film 1305 is at least partially merged (e.g., after epitaxial film crystals grow until touching or coalescing).

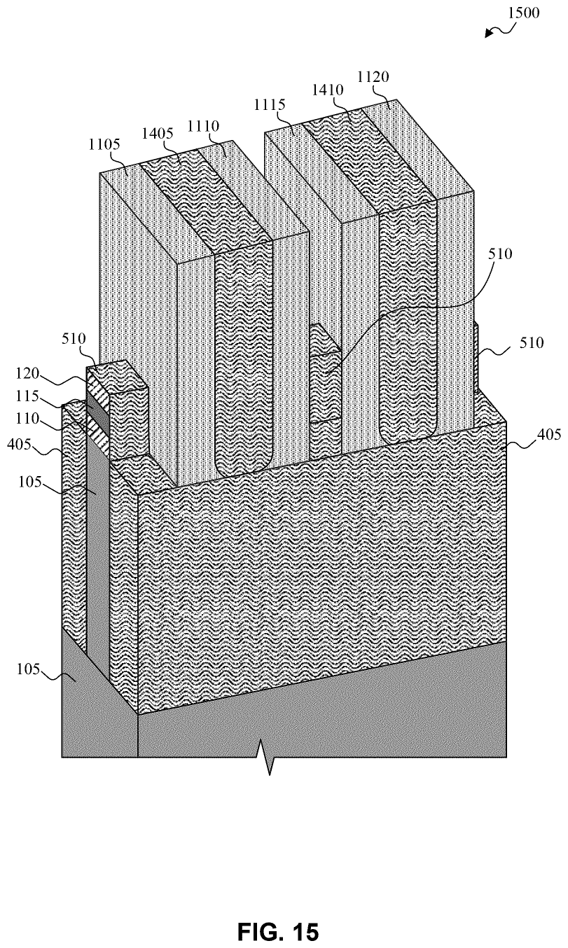

FIG. 15 illustrates an example stack 1500 in accordance with one or more implementations as described herein. In some examples, stack 1500 may depict layers of a semiconductor device (e.g., a semiconductor stack of a transistor). In the illustrated example, stack 1500 may include substrate 105, segments of semiconductor alloy 110, segments of semiconductor 115, segments of semiconductor alloy 120, STI 405, oxide layer 510, sidewalls of gate spacer 805, stressor material 1405, and stressor material 1410. In some cases, portions of inner spacer 1205, inner spacer 1210, inner spacer 1215, inner spacer 1220, inner spacer 1225, inner spacer 1230, and/or epitaxial film 1305 may be embedded in or under sidewalls of gate spacer 805, stressor material 1405, and/or stressor material 1410.

In the illustrated example, the fins of dummy gate 505 may be removed (e.g., via etching, removed from stack 1400). As shown, the sidewalls of gate spacer 805 may remain based on removing the fins of dummy gate 505. Stack 1500 may include one or more fins, where a given fin includes a first sidewall of gate spacer 805, stressor material (e.g., stressor material 1405, stressor material 1410), and a second sidewall of gate spacer 805. As shown, removing the fins of dummy gate 505 exposes the segments of semiconductor alloy 110, segments of semiconductor 115, segments of semiconductor alloy 120 that were embedded in the fins of dummy gate 505. As shown, the segments of semiconductor alloy 110, segments of semiconductor 115, segments of semiconductor alloy 120 may be covered in oxide layer 510. Removing the fins of dummy gate 505 further increases the tensile stress at the segments of semiconductor 115 (e.g., at the silicon channel based on an NMOS design). In some cases, removing the fins of dummy gate 505 decreases a compressive stress on the segments of semiconductor 115, thereby increasing the tensile stress at the segments of semiconductor 115.

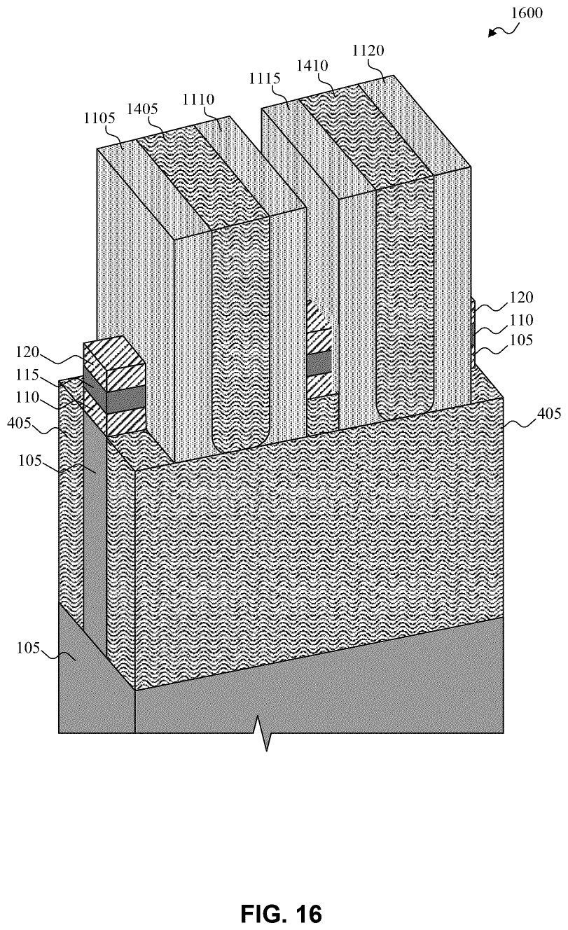

FIG. 16 illustrates an example stack 1600 in accordance with one or more implementations as described herein. In some examples, stack 1600 may depict layers of a semiconductor device (e.g., a semiconductor stack of a transistor). In the illustrated example, stack 1600 may include substrate 105, segments of semiconductor alloy 110, segments of semiconductor 115, segments of semiconductor alloy 120, STI 405, sidewalls of gate spacer 805, stressor material 1405, and stressor material 1410. In some cases, portions of inner spacer 1205, inner spacer 1210, inner spacer 1215, inner spacer 1220, inner spacer 1225, inner spacer 1230, and/or epitaxial film 1305 may be embedded in or under sidewalls of gate spacer 805, stressor material 1405, and/or stressor material 1410. As shown, stack 1600 may include one or more fins (e.g., fins of stack 1600), where a given fin includes a first sidewall of gate spacer 805, stressor material (e.g., stressor material 1405, stressor material 1410), and a second sidewall of gate spacer 805.

In the illustrated example, oxide layer 510 (e.g., of stack 1500) may be removed, exposing the segments of semiconductor alloy 110, segments of semiconductor 115, and segments of semiconductor alloy 120 between the fins of stack 1600. In some examples, removing the fins of dummy gate 505 further increases the tensile stress at the segments of semiconductor 115 (e.g., at the silicon channel based on an NMOS design).

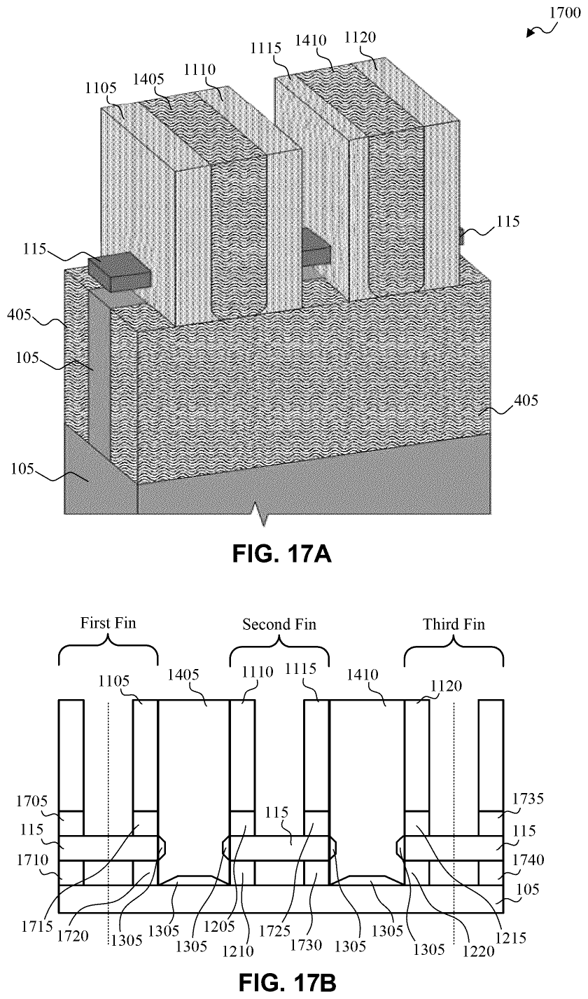

FIG. 17A illustrates an example stack 1700 in accordance with one or more implementations as described herein. In some examples, stack 1700 may depict layers of a semiconductor device (e.g., a semiconductor stack of a transistor). In the illustrated example, stack 1700 may include substrate 105, segments of semiconductor 115, STI 405, sidewalls of gate spacer 805, stressor material 1405, and stressor material 1410. In some cases, portions of inner spacer 1205, inner spacer 1210, inner spacer 1215, inner spacer 1220, inner spacer 1225, inner spacer 1230, and/or epitaxial film 1305 may be embedded in or under sidewalls of gate spacer 805, stressor material 1405, and/or stressor material 1410. As shown, stack 1700 may include one or more fins (e.g., fins of stack 1700), where a given fin includes a first sidewall of gate spacer 805, stressor material (e.g., stressor material 1405, stressor material 1410), and a second sidewall of gate spacer 805.

In the illustrated example, segments of semiconductor alloy 110 and/or segments of semiconductor alloy 120 may be removed from stack 1700 (e.g., from stack 1600 based on etching), leaving segments of semiconductor 115. Based on removing segments of semiconductor alloy 110 and/or segments of semiconductor alloy 120, a portion of inner spacer (e.g., inner spacer 1205, inner spacer 1210, inner spacer 1215, and/or inner spacer 1220) may be exposed above or below the segments of semiconductor 115, within a cavity of a sidewall of gate spacer 805 above or below the segments of semiconductor 115. In some examples, removing the segments of semiconductor alloy 110 and/or segments of semiconductor alloy 120 may reduce tensile stress (or increase compressive stress) in the segments of semiconductor 115 (e.g., in the silicon channel).

FIG. 17B illustrates a side view of stack 1700 in accordance with one or more implementations as described herein. In some examples, stack 1700 may depict layers of a semiconductor device (e.g., a semiconductor stack of a transistor). In the illustrated example, stack 1700 may include substrate 105, segments of semiconductor 115, sidewalls of gate spacer 805 (e.g., first sidewall 1105, second sidewall 1110, third sidewall 1115, and fourth sidewall 1120), inner spacer 1205, inner spacer 1210, inner spacer 1215, inner spacer 1220, stressor material 1405, stressor material 1410, inner spacer 1705, inner spacer 1710, inner spacer 1715, and inner spacer 1720, inner spacer 1725, and inner spacer 1730, inner spacer 1735, and inner spacer 1740. In some cases, a material of a sidewall of gate spacer 805 may be the same material as that of an inner spacer of FIG. 17B (e.g., inner spacer 1705, etc.). In some cases, portions of inner spacer 1205, inner spacer 1210, inner spacer 1215, inner spacer 1220, inner spacer 1225, and/or inner spacer 1230, may be embedded in or under sidewalls of gate spacer 805, stressor material 1405, and/or stressor material 1410. As shown, epitaxial film 1305 may be embedded in stressor material 1405, and/or stressor material 1410.

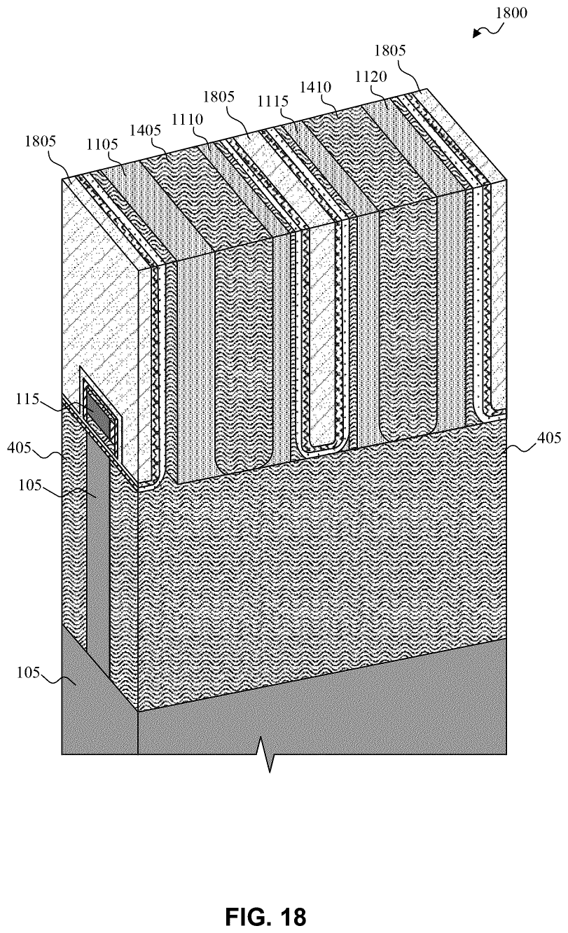

FIG. 18 illustrates an example stack 1800 in accordance with one or more implementations as described herein. In some examples, stack 1800 may depict layers of a semiconductor device (e.g., a semiconductor stack of a transistor). In the illustrated example, stack 1800 may include substrate 105, STI 405, sidewalls of gate spacer 805, second sidewall 1110, third sidewall 1115, stressor material 1405, stressor material 1410, and gate material 1805. In some cases, portions of inner spacer 1205, inner spacer 1210, inner spacer 1215, inner spacer 1220, inner spacer 1225, inner spacer 1230, and/or epitaxial film 1305 may be embedded in or under sidewalls of gate spacer 805, stressor material 1405, and/or stressor material 1410.

In the illustrated example, gate material 1805 may be deposited in an open space (e.g., an open space of stack 1700) between second sidewall 1110 and third sidewall 1115. As shown, additional gate material may be deposited between other or adjacent open spaces between other sidewalls of gate spacer 805. In some examples, segments of semiconductor 115 may be embedded in or under deposits of gate material 1805. In some cases, gate material 1805 may include replacement metal gate (RMG) material. In some cases, depositing gate material 1805 locks in a stress profile of the segments of semiconductor 115 (e.g., in the silicon channel of stack 1800, due to high Young's modulus of gate material 1805, for example). In some cases, gate material 1805 may include an interfacial layer (e.g., silicon oxide). In some cases, gate material 1805 may include a high-K material (e.g., high-K dielectric, material with high dielectric constant, hafnium oxide, etc.). In some cases, gate material 1805 may include a metal (e.g., a relatively hard material, conductive material, tungsten, etc.).

Before the metal is added (e.g., to gate material 1805), an oxide may be deposited and a high-K material (e.g., without interfacial oxide layer). In some cases, an interfacial oxide layer may be deposited on the silicon channel (e.g., based on the silicon oxide being grown on the silicon surface using oxidation process). In some cases, the high-K material may be deposited conformally (e.g., based on atomic layer deposition). After the high-K material, a metal (e.g., tungsten) may be deposited to fill in the remaining gap. In some cases, chemical-mechanical planarization may be performed to make the top surface flat.

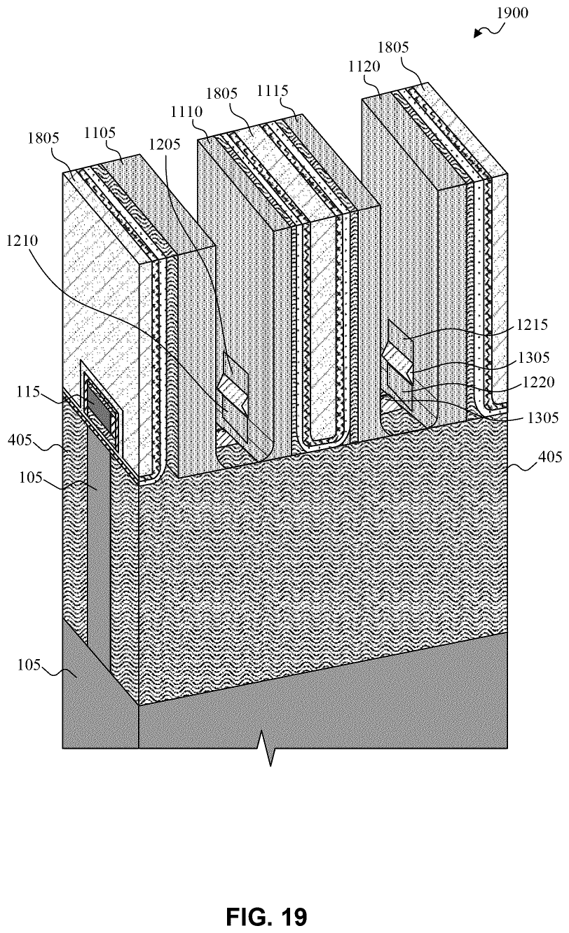

FIG. 19 illustrates an example stack 1900 in accordance with one or more implementations as described herein. In some examples, stack 1900 may depict layers of a semiconductor device (e.g., a semiconductor stack of a transistor). In the illustrated example, stack 1900 may include substrate 105, segments of semiconductor alloy 110, segments of semiconductor 115, segments of semiconductor alloy 120, STI 405, sidewalls of gate spacer 805, first sidewall 1105, second sidewall 1110, third sidewall 1115, fourth sidewall 1120, inner spacer 1205, inner spacer 1210, inner spacer 1215, inner spacer 1220, and gate material 1805. As shown, stack 1900 may include one or more fins (e.g., fins of stack 1900), where a given fin includes second sidewall 1110, gate material 1805, and third sidewall 1115. In some examples, segments of semiconductor 115 may be embedded in or under deposits of gate material 1805.

In the illustrated example, stressor material 1405 and/or stressor material 1410 may be removed from stack 1900 (e.g., from stack 1800). In some cases, removing stressor material 1405 and/or stressor material 1410 may expose portions of inner spacer 1205, inner spacer 1210, inner spacer 1215, inner spacer 1220, and/or epitaxial film 1305. In some cases, the stress profile of the segments of semiconductor 115 (e.g., in the silicon channel of stack 1800) with stressor material 1405 and/or stressor material 1410 may be maintained after removing stressor material 1405 and/or stressor material 1410. For example, based on gate material 1805 locking in the stress profile of stack 1900 (e.g., due to high Young's modulus of gate material 1805 (e.g., stiff material property)), removing stressor material 1405 and/or stressor material 1410 may not affect the stress profile (e.g., stress level is maintained in the silicon channel).

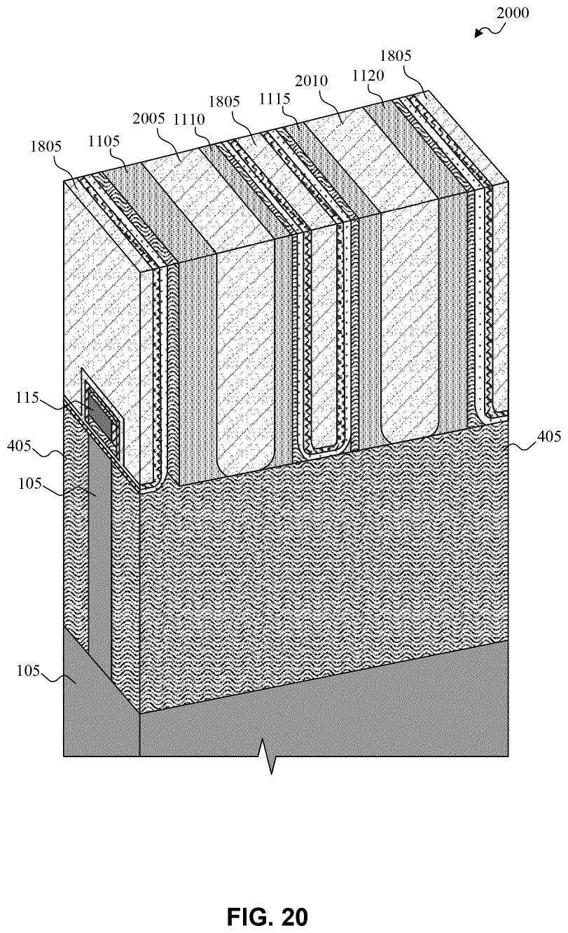

FIG. 20 illustrates an example stack 2000 in accordance with one or more implementations as described herein. In some examples, stack 2000 may depict layers of a semiconductor device (e.g., a semiconductor stack of a transistor). In the illustrated example, stack 2000 may include substrate 105, STI 405, sidewalls of gate spacer 805 (e.g., first sidewall 1105, second sidewall 1110, third sidewall 1115, fourth sidewall 1120), gate material 1805, source material 2005, and drain material 2010. In some cases, portions of inner spacer 1205, inner spacer 1210, inner spacer 1215, inner spacer 1220, inner spacer 1225, inner spacer 1230, and/or epitaxial film 1305 may be embedded in or under sidewalls of gate spacer 805, source material 2005, and/or drain material 2010. In some cases, segments of semiconductor 115 may be embedded in or under gate material 1805.

In the illustrated example, source material 2005 and/or drain material 2010 may be added to stack 2000 (e.g., to stack 1900). As shown, source material 2005 may be added between first sidewall 1105 and second sidewall 1110, and drain material 2010 may be added between third sidewall 1115 and fourth sidewall 1120. Alternatively, drain material 2010 may be added between first sidewall 1105 and second sidewall 1110, and source material 2005 may be added between third sidewall 1115 and fourth sidewall 1120. In some cases, source material 2005 and/or drain material 2010 may include a metal (e.g., a relatively hard material, conductive material, molybdenum, ruthenium, copper, tungsten, etc.). Based on gate material 1805 locking in the stress profile of stack 2000, adding source material 2005 and/or drain material 2010 may not affect the stress profile (e.g., stress level is maintained in the silicon channel).

Based on the systems and methods described herein, multiple advantages and benefits are realized. For example, the systems and methods include applying stress in transistors based on depositing dummy stressor materials (e.g., stressor material 1405, stressor material 1410) to a source and/or drain region of a transistor before depositing a metal gate material (e.g., gate material 1805). Depositing a dummy stress material to source/drain regions of a transistor before depositing a metal gate material improves stress transfer efficiency and avoids the issues of reduced stress that can occur as a result of discontinuous epitaxial growth. Depositing a dummy stress material to source/drain regions of a transistor before depositing a metal gate material provides an optimal amount of stress to a silicon channel of a transistor (e.g., segments of semiconductor 115). The systems and methods described herein are applicable to any transistor structure having a discontinuous epitaxial film in the source and drain (e.g., MBCFETs, FinFET, Forksheet FET, or 3D stacked FET, nanosheet transistors) with an inner spacer, with bottom dielectric isolation (BDI), and/or inner spacer and BDI.

In some cases, the systems and methods described herein may be based on NMOS transistors, where the systems and methods provide tensile stress for the NMOS transistor. The systems and methods described herein may be applied to PMOS transistors. For NMOS transistors, the stressor material (e.g., stressor material 1405, stressor material 1410) may be deposited with tensile stress in NMOS, but may be deposited with compressive stress in PMOS. In some cases, tensile stress corresponds to positive stress (e.g., +1 GPa) and compressive stress corresponds to negative stress (e.g., −1 GPa). For example, “increasing the tensile stress” may indicate that the stress is becoming more positive, while “increasing the compressive stress” may indicate the stress is becoming more negative.

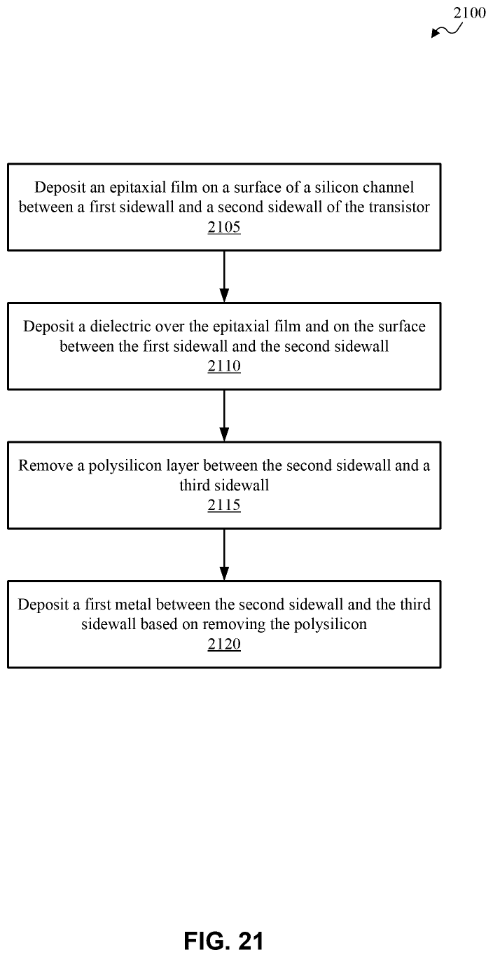

FIG. 21 depicts a flow diagram illustrating an example method 2100 associated with the disclosed systems, in accordance with example implementations described herein. In some configurations, method 2100 may be implemented by one or more semiconductor fabrication devices. The depicted method 2100 is just one implementation and one or more operations of method 2100 may be rearranged, reordered, omitted, and/or otherwise modified such that other implementations are possible and contemplated.

At 2105, method 2100 may include depositing an epitaxial film on a surface of a silicon channel between a first sidewall and a second sidewall of the transistor. For example, a fabrication unit (e.g., via a deposition controller) may deposit an epitaxial film on a surface of a silicon channel between a first sidewall and a second sidewall of the transistor.

At 2110, method 2100 may include depositing a dielectric over the epitaxial film and on the surface between the first sidewall and the second sidewall. For example, a fabrication unit (e.g., via a deposition controller) may deposit a dielectric over the epitaxial film and on the surface between the first sidewall and the second sidewall to increase stress in the silicon channel.

At 2115, method 2100 may include removing a polysilicon layer between the second sidewall and a third sidewall. For example, a fabrication unit (e.g., via a removal controller) may remove a polysilicon layer between the second sidewall and a third sidewall.

At 2120, method 2100 may include depositing a first metal between the second sidewall and the third sidewall based on removing the polysilicon. For example, a fabrication unit (e.g., via a deposition controller) may deposit a first metal between the second sidewall and the third sidewall based on removing the polysilicon.

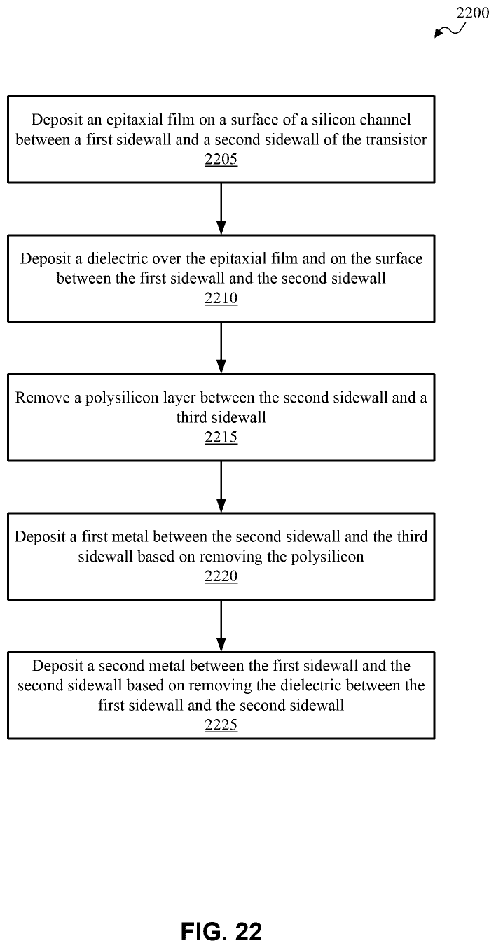

FIG. 22 depicts a flow diagram illustrating an example method 2200 associated with the disclosed systems, in accordance with example implementations described herein. In some configurations, method 2200 may be implemented by one or more semiconductor fabrication devices. The depicted method 2200 is just one implementation and one or more operations of method 2200 may be rearranged, reordered, omitted, and/or otherwise modified such that other implementations are possible and contemplated.

At 2205, method 2200 may include depositing an epitaxial film on a surface of a silicon channel between a first sidewall and a second sidewall of the transistor. For example, a fabrication unit (e.g., via a deposition controller) may deposit an epitaxial film on a surface of a silicon channel between a first sidewall and a second sidewall of the transistor.

At 2210, method 2200 may include depositing a dielectric over the epitaxial film and on the surface between the first sidewall and the second sidewall. For example, a fabrication unit (e.g., via a deposition controller) may deposit a dielectric over the epitaxial film and on the surface between the first sidewall and the second sidewall to increase stress in the silicon channel.

At 2215, method 2200 may include removing a polysilicon layer between the second sidewall and a third sidewall. For example, a fabrication unit (e.g., via a removal controller) may remove a polysilicon layer between the second sidewall and a third sidewall.

At 2220, method 2200 may include depositing a first metal between the second sidewall and the third sidewall based on removing the polysilicon. For example, a fabrication unit (e.g., via a deposition controller) may deposit a first metal between the second sidewall and the third sidewall based on removing the polysilicon.

At 2225, method 2200 may include depositing a second metal between the first sidewall and the second sidewall based on removing the dielectric between the first sidewall and the second sidewall. For example, a fabrication unit (e.g., via a deposition controller and/or a removal controller) may deposit a second metal between the first sidewall and the second sidewall based on removing the dielectric between the first sidewall and the second sidewall.

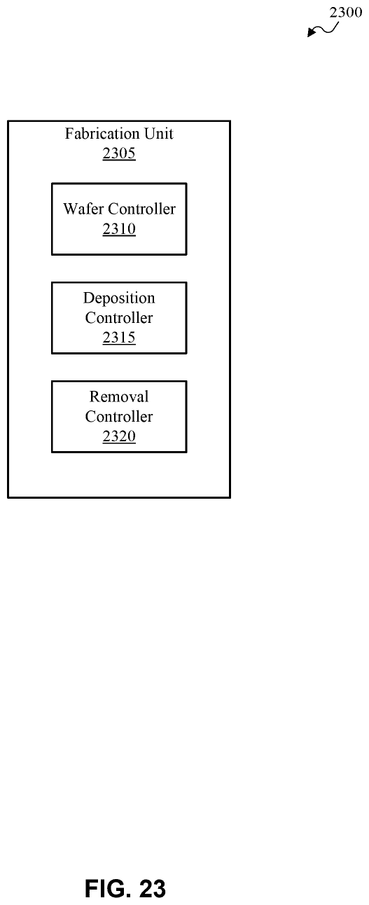

FIG. 23 illustrates an example system 2300 in accordance with one or more implementations as described herein. In the illustrated example, system 2300 may include fabrication unit 2305. As shown, fabrication unit 2305 may include wafer controller 2310, deposition controller 2315, and removal controller 2320.

In some examples, fabrication unit 2305 may be configured to perform semiconductor fabrication. In some cases, fabrication unit 2305 may be configured to fabricate silicon wafers into integrated circuits (ICs). System 2300, fabrication unit 2305, and/or at least one component of fabrication unit 2305 may perform one or more steps (e.g., deposition, removal, etching, doping, oxidation, lithography, metallization, etc.) to fabricate electronic circuits such as computer processors, microcontrollers, memory chips, and transistors, etc. In some cases, fabrication unit 2305 may perform photolithography and/or physio-chemical processes such as thermal oxidation, thin-film deposition, ion-implantation, etching, etc. Processes of fabrication unit 2305 may implement a variety of materials, including silicon, germanium, compound semiconductors, nitrides, dielectrics, etc.

In some cases, wafer controller 2310 may perform wafer preparation, including transforming a semiconductor crystal into a thin, flat wafer with a smooth surface. Wafer controller 2310 may perform crystal growth, wafer slicing, polishing, and cleaning to generate the wafers.

Deposition controller 2315 may perform deposition on semiconductor fabrication. Deposition controller 2315 may perform one or more processes that grow, coat, and/or transfer one or more materials onto the wafer. Deposition controller 2315 may deposit semiconductors, semiconductor compounds (e.g., silicon germanium), metals (e.g., conductive material, tungsten, etc.), dielectrics, and/or other materials. Deposition controller 2315 may perform chemical vapor deposition (CVD), atomic layer deposition (ALD), magnetron sputtering, physical vapor deposition (PVD), and/or other deposition processes to deposit materials onto a wafer, semiconductor devices, etc.

Removal controller 2320 may remove materials from wafer, semiconductor devices, etc. Removal controller 2320 may perform any process that removes material from the wafer, such as wet etch processes, dry etch processes, chemical-mechanical planarization (CMP), and/or other removal processes.

In some examples, fabrication unit 2305 may include less or more components than those depicted in system 2300. In some cases, system 2300 may include one or more devices (e.g., including fabrication unit) to fabricate semiconductor devices such as those described herein.

In the examples described herein, the configurations and operations are example configurations and operations, and may involve various additional configurations and operations not explicitly illustrated. In some examples, one or more aspects of the illustrated configurations and/or operations may be omitted. In some embodiments, one or more of the operations may be performed by components other than those illustrated herein. Additionally, or alternatively, the sequential and/or temporal order of the operations may be varied.

Certain embodiments may be implemented in one or a combination of hardware, firmware, and software. Other embodiments may be implemented as instructions stored on a computer-readable storage device, which may be read and executed by at least one processor to perform the operations described herein. A computer-readable storage device may include any non-transitory memory mechanism for storing information in a form readable by a machine (e.g., a computer). For example, a computer-readable storage device may include read-only memory (ROM), random-access memory (RAM), magnetic disk storage media, optical storage media, flash-memory devices, and other storage devices and media.

The word “exemplary” is used herein to mean “serving as an example, instance, or illustration.” Any embodiment described herein as “exemplary” is not necessarily to be construed as preferred or advantageous over other embodiments. The terms “computing device,” “user device,” “communication station,” “station,” “handheld device,” “mobile device,” “wireless device” and “user equipment” (UE) as used herein refers to a wireless communication device such as a cellular telephone, smartphone, tablet, netbook, wireless terminal, laptop computer, a femtocell, High Data Rate (HDR) subscriber station, access point, printer, point of sale device, access terminal, or other personal communication system (PCS) device. The device may be either mobile or stationary.

As used within this document, the term “communicate” is intended to include transmitting, or receiving, or both transmitting and receiving. This may be particularly useful in claims when describing the organization of data that is being transmitted by one device and received by another, but only the functionality of one of those devices is required to infringe the claim. Similarly, the bidirectional exchange of data between two devices (both devices transmit and receive during the exchange) may be described as ‘communicating’, when only the functionality of one of those devices is being claimed. The term “communicating” as used herein with respect to a wireless communication signal includes transmitting the wireless communication signal and/or receiving the wireless communication signal. For example, a wireless communication unit, which is capable of communicating a wireless communication signal, may include a wireless transmitter to transmit the wireless communication signal to at least one other wireless communication unit, and/or a wireless communication receiver to receive the wireless communication signal from at least one other wireless communication unit.

Although an example processing system has been described above, embodiments of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more components of computer program instructions, encoded on computer storage medium for execution by, or to control the operation of, information/data processing apparatus. Alternatively, or in addition, the program instructions can be encoded on an artificially-generated propagated signal, for example a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (for example multiple CDs, disks, or other storage devices).

The operations described herein can be implemented as operations performed by an information/data processing apparatus on information/data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, for example an FPGA (field programmable gate array) or an ASIC (application-specific integrated circuit). The apparatus can also include, in addition to hardware, code that creates an execution environment for the computer program in question, for example code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a component, component, subroutine, object, or other unit suitable for use in a computing environment. A computer program may, but need not, correspond to a file in a file system. A program can be stored in a portion of a file that holds other programs or information/data (for example one or more scripts stored in a markup language document), in a single file dedicated to the program in question, or in multiple coordinated files (for example files that store one or more components, sub-programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, for example magnetic, magneto-optical disks, or optical disks. However, a computer need not have such devices. Devices suitable for storing computer program instructions and information/data include all forms of non-volatile memory, media and memory devices, including by way of example semiconductor memory devices, for example EPROM, EEPROM, and flash memory devices; magnetic disks, for example internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described herein can be implemented on a computer having a display device, for example a CRT (cathode ray tube) or LCD (liquid crystal display) monitor, for displaying information/data to the user and a keyboard and a pointing device, for example a mouse or a trackball, by which the user can provide input to the computer. Other kinds of devices can be used to provide for interaction with a user as well; for example, feedback provided to the user can be any form of sensory feedback, for example visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described herein can be implemented in a computing system that includes a back-end component, for example as an information/data server, or that includes a middleware component, for example an application server, or that includes a front-end component, for example a client computer having a graphical user interface or a web browser through which a user can interact with an embodiment of the subject matter described herein, or any combination of one or more such back-end, middleware, or front-end components. The components of the system can be interconnected by any form or medium of digital information/data communication, for example a communication network. Examples of communication networks include a local area network (“LAN”) and a wide area network (“WAN”), an inter-network (for example the Internet), and peer-to-peer networks (for example ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits information/data (for example an HTML page) to a client device (for example for purposes of displaying information/data to and receiving user input from a user interacting with the client device). Information/data generated at the client device (for example a result of the user interaction) can be received from the client device at the server.

While this specification contains many specific embodiment details, these should not be construed as limitations on the scope of any embodiment or of what may be claimed, but rather as descriptions of features specific to particular embodiments. Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain embodiments, multitasking and parallel processing may be advantageous.

Many modifications and other examples described herein set forth herein will come to mind to one skilled in the art to which these embodiments pertain having the benefit of the teachings presented in the foregoing descriptions and the associated drawings. Therefore, it is to be understood that the embodiments are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed:

1. A method of fabricating a transistor, the method comprising:
depositing an epitaxial film on a surface between a first sidewall and a second sidewall of the transistor;
depositing a dielectric over the epitaxial film and on the surface between the first sidewall and the second sidewall to increase stress in a silicon channel of the transistor;
removing a polysilicon fin between the second sidewall and a third sidewall; and
depositing a first metal between the second sidewall and the third sidewall based on removing the polysilicon fin.

2. The method of claim 1, further comprising removing the dielectric between the first sidewall and the second sidewall, wherein depositing the first metal maintains the stress on the silicon channel after removal of the dielectric.

3. The method of claim 2, further comprising depositing a second metal between the first sidewall and the second sidewall based on removing the dielectric.

4. The method of claim 1, wherein:
the epitaxial film includes a first epitaxy portion and a second epitaxy portion, and
the dielectric is deposited over the epitaxial film before the first epitaxy portion is allowed to merge with the second epitaxy portion.

5. The method of claim 1, further comprising removing, between the second sidewall and the third sidewall, a portion of a first silicon germanium layer formed under the silicon channel and a portion of a second silicon germanium layer formed over the silicon channel, wherein removing the first silicon germanium layer and the second silicon germanium layer decreases the stress in the silicon channel.

6. The method of claim 1, further comprising etching a portion of a channel fin between the first sidewall and the second sidewall to form the surface between the first sidewall and the second sidewall.

7. The method of claim 6, further comprising forming the first sidewall, the second sidewall, and the third sidewall over the channel fin, wherein:
the channel fin is transverse to the first sidewall, the second sidewall, and the third sidewall, and
the channel fin comprises the silicon channel.

8. The method of claim 1, wherein removing the polysilicon fin increases the stress of the silicon channel of the transistor.

9. The method of claim 1, wherein the surface between the first sidewall and the second sidewall is associated with a source region of the transistor or a drain region of the transistor.

10. The method of claim 1, wherein an area between the second sidewall and the third sidewall is associated with a gate region of the transistor.

11. A transistor comprising:
an epitaxial film deposited on a surface between a first sidewall and a second sidewall of the transistor;
a dielectric deposited over the epitaxial film and on the surface between the first sidewall and the second sidewall to increase stress in a silicon channel of the transistor; and
a first metal deposited between the second sidewall and a third sidewall based on removing a polysilicon fin, wherein the polysilicon fin between the second sidewall and the third sidewall is removed to allow the first metal to be deposited.

12. The transistor of claim 11, further comprising a second metal deposited between the first sidewall and the second sidewall based on removing the dielectric between the first sidewall and the second sidewall.

13. The transistor of claim 11, wherein:
the epitaxial film includes a first epitaxy portion and a second epitaxy portion, and
the dielectric is deposited over the epitaxial film before the first epitaxy portion is allowed to merge with the second epitaxy portion.

14. The transistor of claim 11, further comprising removing, between the second sidewall and the third sidewall, a portion of a first silicon germanium layer formed under the silicon channel and a portion of a second silicon germanium layer formed over the silicon channel, wherein removing the first silicon germanium layer and the second silicon germanium layer decreases the stress in the silicon channel.

15. The transistor of claim 11, further comprising a portion of a channel fin between the first sidewall and the second sidewall that is etched to form the surface between the first sidewall and the second sidewall.

16. The transistor of claim 15, further comprising the first sidewall, the second sidewall, and the third sidewall formed over the channel fin, wherein:
the channel fin is transverse to the first sidewall, the second sidewall, and the third sidewall, and
the channel fin comprises the silicon channel.

17. The transistor of claim 11, wherein:
the surface between the first sidewall and the second sidewall is associated with a source region of the transistor or a drain region of the transistor, and
an area between the second sidewall and the third sidewall is associated with a gate region of the transistor.

18. A fabrication system comprising:
a deposition controller to:
deposit an epitaxial film on a surface between a first sidewall and a second sidewall of a transistor; and
deposit a dielectric over the epitaxial film and on the surface between the first sidewall and the second sidewall to increase stress in a silicon channel of the transistor;
a removal controller to remove a polysilicon fin between the second sidewall and a third sidewall; and
the deposition controller to deposit a first metal between the second sidewall and the third sidewall based on removal of the polysilicon fin.

19. The fabrication system of claim 18, the removal controller being further configured to remove the dielectric between the first sidewall and the second sidewall, wherein depositing the first metal maintains the stress on the silicon channel after removal of the dielectric.

20. The fabrication system of claim 19, the deposition controller being further configured to deposit a second metal between the first sidewall and the second sidewall based on removal of the dielectric.
